(19) United States
(12) Patent Application Publication
(10) Pub. No.: US 2024/0282656 A1
(43) Pub. Date: Aug. 22, 2024

(54) SEMICONDUCTOR MODULE

(71) Applicant: ROHM CO., LTD., Kyoto-shi (JP)

(72) Inventor: Yuki NAKANO, Kyoto-shi (JP)

(73) Assignee: ROHM CO., LTD., Kyoto-shi (JP)

(21) Appl. No.: 18/651,815

(22) Filed: May 1, 2024

Related U.S. Application Data
(63) Continuation of application No. PCT/JP2022/040505, filed on Oct. 28, 2022.

(30) Foreign Application Priority Data
Nov. 5, 2021 (JP) 2021-181324

(51) Int. Cl. H01L 23/31; H01L 23/00; H01L 23/29

(52) U.S. Cl. CPC H01L 23/3135; H01L 23/296; H01L 24/48; H01L 2224/48227

(57) ABSTRACT

A semiconductor module includes a housing that has a housing space, a semiconductor device that is arranged in the housing space, and that has a chip having a main surface, a main surface electrode arranged on the main surface, a terminal electrode arranged on the main surface electrode, and a sealing insulator covering a periphery of the terminal electrode on the main surface such as to expose a part of the terminal electrode, and an insulating gel-like filling agent that is filled in the housing space such as to contact the sealing insulator, and that seals the semiconductor device in the housing space.

### CROSS-REFERENCE TO RELATED APPLICATIONS

The present application is a bypass continuation of International Patent Application No. PCT/JP2022/040505, filed on Oct. 28, 2022, which claims the benefit of priority to Japanese Patent Application No. 2021-181324 filed on Nov. 5, 2021, and the entire contents of each application are hereby incorporated herein by reference.

### BACKGROUND

### 1. Field of the Disclosure

The present disclosure relates to a semiconductor module.

### 2. Description of the Related Art

US20190080976A1 discloses a semiconductor device that includes a semiconductor substrate, an electrode and a protective film. The electrode is formed on the semiconductor substrate. The protective film has a laminated structure that includes an inorganic protective film and an organic protective film and covers the electrode.

### BRIEF DESCRIPTION OF THE DRAWINGS

FIG. 1 is a plan view of a semiconductor device according to a first embodiment.

FIG. 2 is a cross sectional view taken along II-II line shown in FIG. 1.

FIG. 3 is an enlarged plan view showing a principal part of an inner portion of a chip.

FIG. 4 is a cross sectional view taken along IV-IV line shown in FIG. 3.

FIG. 5 is an enlarged cross sectional view showing a peripheral portion of the chip.

FIG. 6 is a plan view showing layout examples of a gate electrode and a source electrode.

FIG. 7 is a plan view showing a layout example of an upper insulating film.

FIG. 8 is a plan view showing a semiconductor module according to a first mode example in which the semiconductor device shown in FIG. 1 is mounted.

FIG. 9 is a cross sectional view showing the semiconductor module shown in FIG. 8.

FIG. 10 is a circuit diagram showing the semiconductor module shown in FIG. 8.

FIG. 11 is a plan view showing a semiconductor module according to a second mode example in which the semiconductor device shown in FIG. 1 is mounted.

FIG. 12 is a circuit diagram showing the semiconductor module shown in FIG. 11.

FIG. 13 is a plan view showing a semiconductor device according to a second embodiment.

FIG. 14 is a plan view showing a semiconductor device according to a third embodiment.

FIG. 15 is a cross sectional view taken along XV-XV line shown in FIG. 14.

FIG. 16 is a circuit diagram showing an electrical configuration of the semiconductor device shown in FIG. 14.

FIG. 17 is a plan view showing a semiconductor device according to a fourth embodiment.

FIG. 18 is a cross sectional view taken along XVIII-XVIII line shown in FIG. 17.

FIG. 19 is a plan view showing a semiconductor device according to a fifth embodiment.

FIG. 20 is a plan view showing a semiconductor device according to a sixth embodiment.

FIG. 21 is a plan view showing a semiconductor device according to a seventh embodiment.

FIG. 22 is a plan view showing a semiconductor device according to an eighth embodiment.

FIG. 23 is a cross sectional view taken along XXIII-XXIII line shown in FIG. 22.

FIG. 24 is a cross sectional view showing a modified example of the chip to be applied to each of the embodiments.

FIG. 25 is a cross sectional view showing a modified example of a sealing insulator to be applied to each of the embodiments.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference symbols are given to corresponding structures among the attached drawings, and duplicate descriptions thereof shall be omitted or simplified. For the structures, whose description have been omitted or simplified, the description given before the omission or simplification shall be applies.

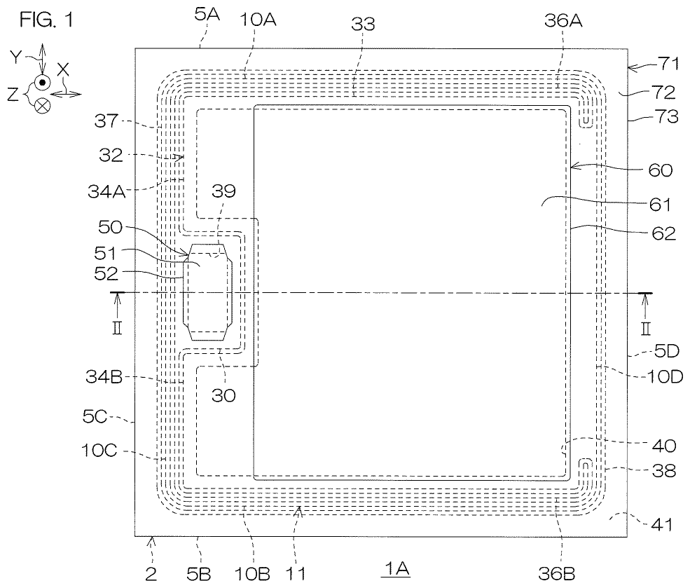

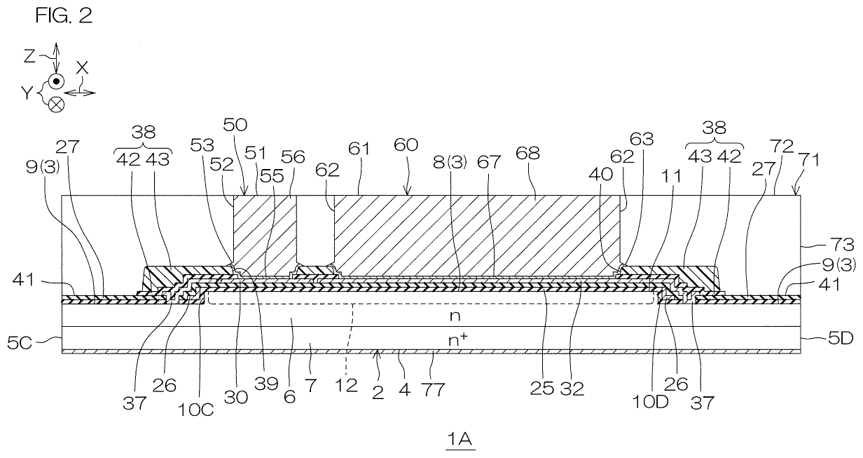

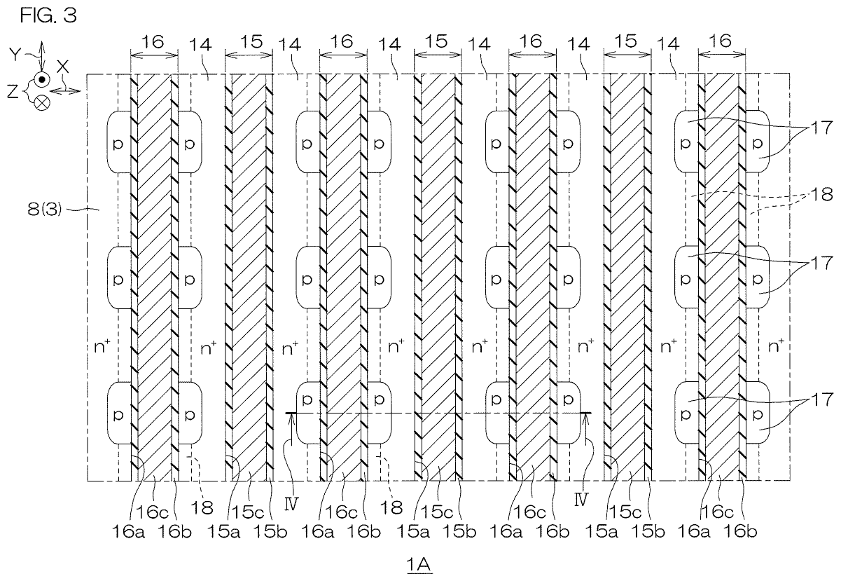

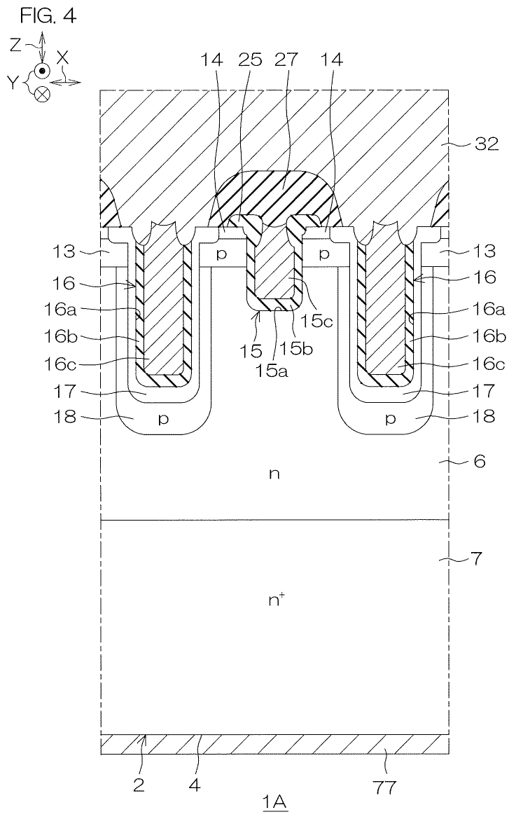

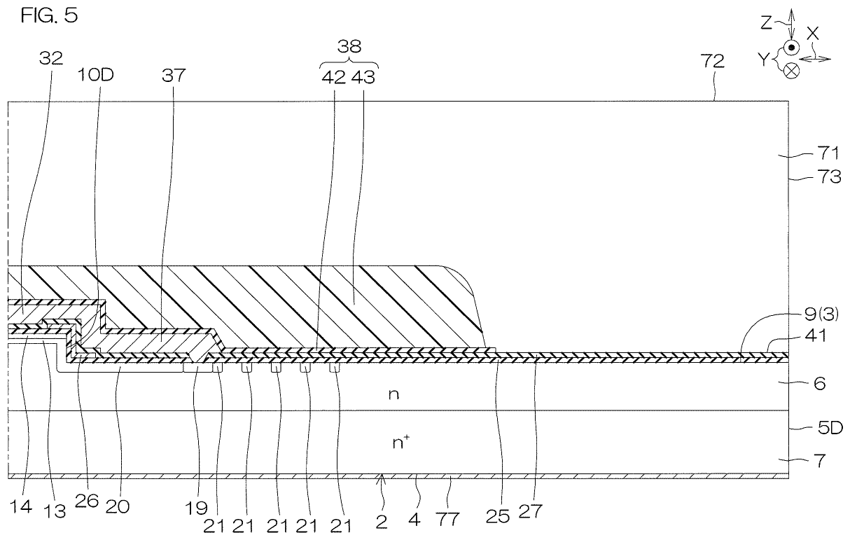

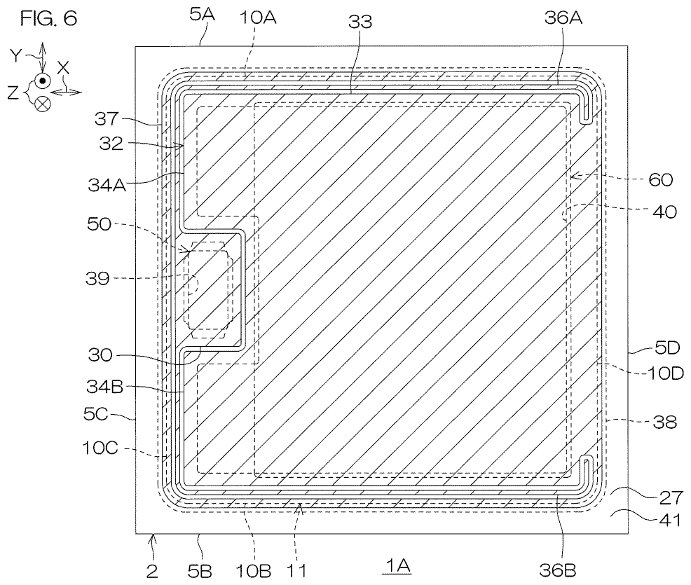

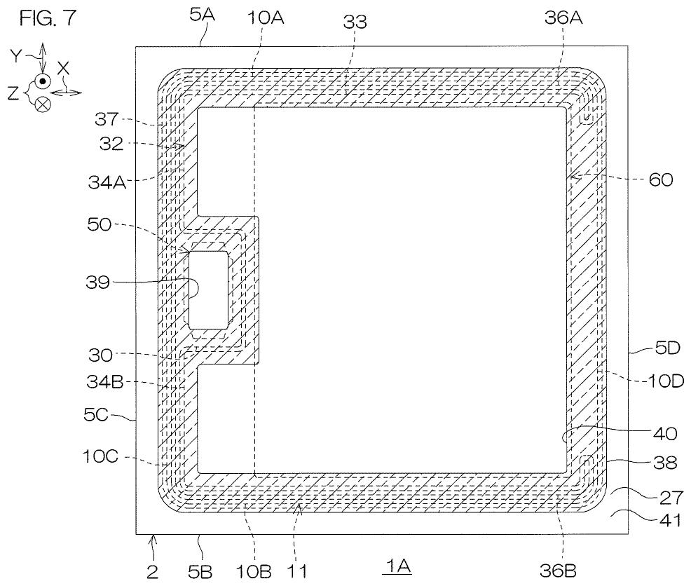

FIG. 1 is a plan view of a semiconductor device 1A according to a first embodiment. FIG. 2 is a cross sectional view taken along II-II line shown in FIG. 1. FIG. 3 is an enlarged plan view showing a principal part of an inner portion of a chip 2. FIG. 4 is a cross sectional view taken along IV-IV line shown in FIG. 3. FIG. 5 is an enlarged cross sectional view showing a peripheral portion of the chip 2. FIG. 6 is a plan view showing layout examples of a gate electrode 30 and a source electrode 32. FIG. 7 is a plan view showing a layout example of an upper insulating film 38.

With reference to FIG. 1 to FIG. 7, the semiconductor device 1A includes a chip 2 that includes a monocrystal of a wide bandgap semiconductor and that is formed in a hexahedral shape (specifically, rectangular parallelepiped shape), in this embodiment. That is, the semiconductor device 1A is a “wide bandgap semiconductor device”. The chip 2 may be referred to as a “semiconductor chip” or a “wide bandgap semiconductor chip”. The wide bandgap semiconductor is a semiconductor having a bandgap exceeding a bandgap of an Si (Silicon). GaN (gallium nitride), SiC (silicon carbide) and C (diamond) are exemplified as the wide bandgap semiconductors.

The chip 2 is an “SiC chip” including an SiC monocrystal of a hexagonal crystal as an example of the wide bandgap semiconductor. That is, the semiconductor device 1A is an “SiC semiconductor device”.

The SiC monocrystal of the hexagonal crystal has multiple polytypes including 2H (Hexagonal)-SiC monocrystal, 4H-SiC monocrystal, 6H-SiC monocrystal and the like. In this embodiment, an example in which the chip 2 includes the 4H-SiC monocrystal is to be given, but this does not preclude a choice of other polytypes.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed from their normal direction Z (hereinafter, simply referred to as “in plan view”). The normal direction Z is also a thickness direction of the chip 2. The first main surface 3 and the second main surface 4 are preferably formed by a c-plane of the SiC monocrystal, respectively.

In this case, the first main surface 3 is preferably formed by a silicon surface of the SiC monocrystal, and the second main surface 4 is preferably formed by a carbon surface of the SiC monocrystal. The first main surface 3 and the second main surface 4 may each have an off angle inclined with a predetermined angle with respect to the c-plane toward a predetermined off direction. The off direction is preferably an a-axis direction ( [11-20] direction) of the SiC monocrystal. The off angle may be more than 0° and not more than 10°. The off angle is preferably not more than 5°. The second main surface 4 may consist of a ground surface with grinding marks, or may consist of a smooth surface without a grinding mark.

The first side surface 5A and the second side surface 5B extend in a first direction X along the first main surface 3 and oppose in a second direction Y intersecting to (specifically, orthogonal to) the first direction X. The third side surface 5C and the fourth side surface 5D extend in the second direction Y and oppose in the first direction X. The first direction X may be an m-axis direction ( [1-100] direction) of the SiC monocrystal, and the second direction Y may be the a-axis direction of the SiC monocrystal. As a matter of course, the first direction X may be the a-axis direction of the SiC monocrystal, and the second direction Y may be the m-axis direction of the SiC monocrystal. The first to fourth side surfaces 5A to 5D may each consist of a ground surface with grinding marks, or may each consist of a smooth surface without a grinding mark.

The chip 2 has a thickness of not less than 5 μm and not more than 250 μm in regard to the normal direction Z. The thickness of the chip 2 may be not more than 100 μm. The thickness of the chip 2 is preferably not more than 50 μm. The thickness of the chip 2 is particularly preferably not more than 40 μm. The first to fourth side surfaces 5A to 5D may each have a length of not less than 0.5 mm and not more than 10 mm in plan view.

The lengths of the first to fourth side surfaces 5A to 5D are preferably not less than 1 mm. The lengths of the first to fourth side surfaces 5A to 5D are particularly preferably not less than 2 mm. That is, the chip 2 preferably has a planar area of not less than 1 mm square (preferably, not less than 2 mm square) and preferably has a thickness of not more than 100 μm (preferably, not more than 50 μm). The lengths of the first to fourth side surfaces 5A to 5D are set in a range of not less than 4 mm and not more than 6 mm, in this embodiment.

The semiconductor device 1A includes a first semiconductor region 6 of an n-type (first conductivity type) that is formed in a region (surface layer portion) on the first main surface 3 side inside the chip 2. The first semiconductor region 6 is formed in a layered shape extending along the first main surface 3 and is exposed from the first main surface 3 and the first to fourth side surfaces 5A to 5D. The first semiconductor region 6 consists of an epitaxial layer (specifically, an SiC epitaxial layer), in this embodiment. The first semiconductor region 6 may have a thickness of not less than 1 μm and not more than 50 μm in regard to the normal direction Z. The thickness of the first semiconductor region 6 is preferably not less than 3 μm and not more than 30 μm. The thickness of the first semiconductor region 6 is particularly preferably not less than 5 μm and not more than 25 μm.

The semiconductor device 1A includes a second semiconductor region 7 of the n-type that is formed in a region (surface layer portion) on the second main surface 4 side inside the chip 2. The second semiconductor region 7 is formed in a layered shape extending along the second main surface 4 and exposes from the second main surface 4 and the first to fourth side surfaces 5A to 5D. The second semiconductor region 7 has an n-type impurity concentration higher than that of the first semiconductor region 6 and is electrically connected to the first semiconductor region 6. The second semiconductor region 7 consists of a semiconductor substrate (specifically, an SiC semiconductor substrate), in this embodiment. That is, the chip 2 has a laminated structure including the semiconductor substrate and the epitaxial layer.

The second semiconductor region 7 may have a thickness of not less than 1 μm and not more than 200 μm, in regard to the normal direction Z. The thickness of the second semiconductor region 7 is preferably not less than 5 μm and not more than 50 μm. The thickness of the second semiconductor region 7 is particularly preferably not less than 5 μm and not more than 20 μm. Considering an error to be occurred to the first semiconductor region 6, the thickness of the second semiconductor region 7 is preferably not less than 10 μm. The thickness of the second semiconductor region 7 is most preferably less than the thickness of the first semiconductor region 6. According to the second semiconductor region 7 having the relatively small thickness, a resistance value (for example, an on-resistance) due to the second semiconductor region 7 can be reduced. As a matter of course, the thickness of the second semiconductor region 7 may exceed the thickness of first semiconductor region 6.

The semiconductor device 1A includes an active surface 8 (active surface), an outer surface 9 (outer surface) and first to fourth connecting surfaces 10A to 10D (connecting surface) that are formed in the first main surface 3. The active surface 8, the outer surface 9 and the first to fourth connecting surfaces 10A to 10D define a mesa portion 11 (plateau) in the first main surface 3. The active surface 8 may be referred to as a “first surface portion”, the outer surface 9 may be referred to as a “second surface portion”, the first to fourth connecting surfaces 10A to 10D may be referred to as “connecting surface portions”. The active surface 8, the outer surface 9 and the first to fourth connecting surfaces 10A to 10D (that is, the mesa portion 11) may be considered as components of the chip 2 (the first main surface 3).

The active surface 8 is formed at an interval inward from a peripheral edge of the first main surface 3 (the first to fourth side surfaces 5A to 5D). The active surface 8 has a flat surface extending in the first direction X and the second direction Y. The active surface 8 is formed in a quadrangle shape having four sides parallel to the first to fourth side surfaces 5A to 5D in plan view, in this embodiment.

The outer surface 9 is positioned outside the active surface 8 and is recessed toward the thickness direction of the chip 2 (the second main surface 4 side) from the active surface 8. Specifically, the outer surface 9 is recessed with a depth less than the thickness of the first semiconductor region 6 such as to expose the first semiconductor region 6. The outer surface 9 extends along the active surface 8 in a band shape and is formed in an annular shape (specifically, a quadrangle annular shape) surrounding the active surface 8 in plan view. The outer surface 9 has a flat surface extending in the first direction X and the second direction Y and is formed substantially parallel to the active surface 8. The outer surface 9 is continuous to the first to fourth side surfaces 5A to 5D.

The first to fourth connecting surfaces 10A to 10D extend in the normal direction Z and connect the active surface 8 and the outer surface 9. The first connecting surface 10A is positioned on the first side surface 5A side, the second connecting surface 10B is positioned on the second side surface 5B side, the third connecting surface 10C is positioned on the third side surface 5C side, and the fourth connecting surface 10D is positioned on the fourth side surface 5D side. The first connecting surface 10A and the second connecting surface 10B extend in the first direction X and oppose in the second direction Y. The third connecting surface 10C and the fourth connecting surface 10D extend in the second direction Y and oppose in the first direction X.

The first to fourth connecting surfaces 10A to 10D may substantially vertically extend between the active surface 8 and the outer surface 9 such that the mesa portion 11 of a quadrangle columnar is defined. The first to fourth connecting surfaces 10A to 10D may be downwardly inclined from the active surface 8 to the outer surface 9 such that the mesa portion 11 of a quadrangle pyramid shape is defined. Thus, the semiconductor device 1A includes the mesa portion 11 that is formed in the first semiconductor region 6 at the first main surface 3. The mesa portion 11 is formed only in the first semiconductor region 6 and is not formed in the second semiconductor region 7.

The semiconductor device 1A includes a MISFET (Metal Insulator Semiconductor Field Effect Transistor) structure 12 that is formed in the active surface 8 (the first main surface 3). In FIG. 2, the MISFET structure 12 is shown simplified by a dashed line. Hereinafter, with reference to FIG. 3 and FIG. 4, a specific structure of the MISFET structure 12 shall be described.

The MISFET structure 12 includes a body region 13 of a p-type (second conductivity type) that is formed in a surface layer portion of the active surface 8. The body region 13 is formed at an interval to the active surface 8 side from a bottom portion of the first semiconductor region 6. The body region 13 is formed in a layered shape extending along the active surface 8. The body region 13 may be exposed from parts of the first to fourth connecting surfaces 10A to 10D.

The MISFET structure 12 includes a source region 14 of the n-type that is formed in a surface layer portion of the body region 13. The source region 14 has an n-type impurity concentration higher than that of the first semiconductor region 6. The source region 14 is formed at an interval to the active surface 8 side from a bottom portion of the body region 13. The source region 14 is formed in a layered shape extending along the active surface 8. The source region 14 may be exposed from a whole region of the active surface 8. The source region 14 may be exposed from parts of the first to fourth connecting surfaces 10A to 10D. The source region 14 forms a channel inside the body region 13 between the first semiconductor region 6 and the source region 14.

The MISFET structure 12 includes a plurality of gate structures 15 that are formed in the active surface 8. The plurality of gate structures 15 arrayed at intervals in the first direction X and each formed in a band shape extending in the second direction Y in plan view. The plurality of gate structures 15 penetrate the body region 13 and the source region 14 such as to reach the first semiconductor region 6. The plurality of gate structures 15 control a reversal and a non-reversal of the channel in the body region 13.

Each of the gate structures 15 includes a gate trench 15a, a gate insulating film 15b and a gate embedded electrode 15c, in this embodiment. The gate trench 15a is formed in the active surface 8 and defines a wall surface of the gate structure 15. The gate insulating film 15b covers the wall surface of the gate trench 15a. The gate embedded electrode 15c is embedded in the gate trench 15a with the gate insulating film 15b interposed therebetween and faces the channel across the gate insulating film 15b.

The MISFET structure 12 includes a plurality of source structures 16 that are formed in the active surface 8. The plurality of source structures 16 are each arranged at a region between a pair of adjacent gate structures 15 in the active surface 8. The plurality of source structures 16 are each formed in a band shape extending in the second direction Y in plan view. The plurality of source structures 16 penetrate the body region 13 and the source region 14 to reach the first semiconductor region 6. The plurality of source structures 16 have depths exceeding depths of the gate structures 15. Specifically, the plurality of source structures 16 has the depths substantially equal to the depth of the outer surface 9.

Each of the source structures 16 includes a source trench 16a, a source insulating film 16b and a source embedded electrode 16c. The source trench 16a is formed in the active surface 8 and defines a wall surface of the source structure 16. The source insulating film 16b covers the wall surface of the source trench 16a. The source embedded electrode 16c is embedded in the source trench 16a with the source insulating film 16b interposed therebetween.

The MISFET structure 12 includes a plurality of contact regions 17 of the p-type that are each formed in a region along the source structure 16 inside the chip 2. The plurality of contact regions 17 have p-type impurity concentration higher than that of the body region 13. Each of the contact regions 17 covers the side wall and the bottom wall of each of the source structures, and is electrically connected to the body region 13.

The MISFET structure 12 includes a plurality of well regions 18 of the p-type that are each formed in a region along the source structure 16 inside the chip 2. Each of the well regions 18 may have a p-type impurity concentration higher than that of the body region 13 and less than that of the contact regions 17. Each of the well regions 18 covers the corresponding source structure 16 with the corresponding contact region 17 interposed therebetween. Each of the well regions 18 covers the side wall and the bottom wall of the corresponding source structure 16, and is electrically connected to the body region 13 and the contact regions 17.

With reference to FIG. 5, the semiconductor device 1A includes an outer contact region 19 of the p-type that is formed in a surface layer portion of the outer surface 9. The outer contact region 19 has a p-type impurity concentration higher than that of the body region 13. The outer contact region 19 is formed at intervals from a peripheral edge of the active surface 8 and a peripheral edge of the outer surface 9, and is formed in a band shape extending along the active surface 8 in plan view.

The outer contact region 19 is formed in an annular shape (specifically, a quadrangle annular shape) surrounding the active surface 8 in plan view, in this embodiment. The outer contact region 19 is formed at an interval to the outer surface 9 side from the bottom portion of the first semiconductor region 6. The outer contact region 19 is positioned on the bottom portion side of the first semiconductor region 6 with respect to the bottom walls of the plurality of gate structures 15 (the plurality of source structures 16).

The semiconductor device 1A includes an outer well region 20 of the p-type that is formed in the surface layer portion of the outer surface 9. The outer well region 20 has a p-type impurity concentration less than that of the outer contact region 19. The p-type impurity concentration of the outer well region 20 is preferably substantially equal to the p-type impurity concentration of the well regions 18. The outer well region 20 is formed in a region between the peripheral edge of the active surface 8 and the outer contact region 19, and is formed in a band shape extending along the active surface 8 in plan view.

The outer well region 20 is formed in an annular shape (specifically, a quadrangle annular shape) surrounding the active surface 8 in plan view, in this embodiment. The outer well region 20 is formed at an interval to the outer surface 9 side from the bottom portion of the first semiconductor region 6. The outer well region 20 may be formed deeper than the outer contact region 19. The outer well region 20 is positioned on the bottom portion side of the first semiconductor region 6 with respect to the plurality of gate structures 15 (the plurality of source structures 16).

The outer well region 20 is electrically connected to the outer contact region 19. The outer well region 20 extends toward the first to fourth connecting surfaces 10A to 10D side from the outer contact region 19 side, and covers the first to fourth connecting surfaces 10A to 10D, in this embodiment. The outer well region 20 is electrically connected to the body region 13 in the surface layer portion of the active surface 8.

The semiconductor device 1A includes at least one (preferably, not less than 2 and not more than 20) field region 21 of the p-type that is formed in a region between the peripheral edge of the outer surface 9 and the outer contact region 19 in the surface layer portion of the outer surface 9. The semiconductor device 1A includes five field regions 21, in this embodiment. The plurality of field regions 21 relaxes an electric field inside the chip 2 at the outer surface 9. A number, a width, a depth, a p-type impurity concentration, etc., of the field region 21 are arbitrary, and various values can be taken depending on the electric field to be relaxed.

The plurality of field regions 21 are arrayed at intervals from the outer contact region 19 side to the peripheral edge side of the outer surface 9. The plurality of field regions 21 are each formed in a band shape extending along the active surface 8 in plan view. The plurality of field regions 21 are each formed in an annular shape (specifically, a quadrangle annular shape) surrounding the active surface 8 in plan view, in this embodiment. Thus, the plurality of field regions 21 are each formed as an FLR (Field Limiting Ring) region.

The plurality of field regions 21 are formed at intervals to the outer surface 9 side from the bottom portion of the first semiconductor region 6. The plurality of field regions 21 are positioned on the bottom portion side of the first semiconductor region 6 with respect to the bottom walls of the plurality of gate structures 15 (the plurality of source structures 16). The plurality of field regions 21 may be formed deeper than the outer contact region 19. The innermost field region 21 may be connected to the outer contact region 19.

The semiconductor device 1A includes a main surface insulating film 25 that covers the first main surface 3. The main surface insulating film 25 may include at least one of a silicon oxide film, a silicon nitride film and a silicon oxynitride film. The main surface insulating film 25 has a single layered structure consisting of the silicon oxide film, in this embodiment. The main surface insulating film 25 particularly preferably includes the silicon oxide film that consists of an oxide of the chip 2.

The main surface insulating film 25 covers the active surface 8, the outer surface 9 and the first to fourth connecting surfaces 10A to 10D. The main surface insulating film 25 covers the active surface 8 such as to be continuous to the gate insulating film 15b and the source insulating film 16b and to expose the gate embedded electrode 15c and the source embedded electrode 16c. The main surface insulating film 25 covers the outer surface 9 and the first to fourth connecting surfaces 10A to 10D such as to cover the outer contact region 19, the outer well region 20 and the plurality of field regions 21.

The main surface insulating film 25 may be continuous to the first to fourth side surfaces 5A to 5D. In this case, an outer wall of the main surface insulating film 25 may consist of a ground surface with grinding marks. The outer wall of the main surface insulating film 25 may form a single ground surface with the first to fourth side surfaces 5A to 5D. As a matter of course, the outer wall of the main surface insulating film 25 may be formed at an interval inward from the peripheral edge of the outer surface 9 and may expose the first semiconductor region 6 from a peripheral edge portion of the outer surface 9.

The semiconductor device 1A includes a side wall structure 26 that is formed on the main surface insulating film 25 such as to cover at least one of the first to fourth connecting surfaces 10A to 10D at the outer surface 9. The side wall structure 26 is formed in an annular shape (a quadrangle annular shape) surrounding the active surface 8 in plan view, in this embodiment. The side wall structure 26 may have a portion that overlaps onto the active surface 8. The side wall structure 26 may include an inorganic insulator or a polysilicon. The side wall structure 26 may be a side wall wiring that is electrically connected to the plurality of source structures 16.

The semiconductor device 1A includes an interlayer insulating film 27 that is formed on the main surface insulating film 25. The interlayer insulating film 27 may include at least one of a silicon oxide film, a silicon nitride film and a silicon oxynitride film. The interlayer insulating film 27 has a single layered structure consisting of the silicon oxide film, in this embodiment.

The interlayer insulating film 27 covers the active surface 8, the outer surface 9 and the first to fourth connecting surfaces 10A to 10D with the main surface insulating film 25 interposed therebetween. Specifically, the interlayer insulating film 27 covers the active surface 8, the outer surface 9 and the first to fourth connecting surfaces 10A to 10D across the side wall structure 26. The interlayer insulating film 27 covers the MISFET structure 12 on the active surface 8 side and covers the outer contact region 19, the outer well region 20 and the plurality of field regions 21 on the outer surface 9 side.

The interlayer insulating film 27 is continuous to the first to fourth side surfaces 5A to 5D, in this embodiment. An outer wall of the interlayer insulating film 27 may consist of a ground surface with grinding marks. The outer wall of the interlayer insulating film 27 may form a single ground surface with the first to fourth side surfaces 5A to 5D. As a matter of course, the outer wall of the interlayer insulating film 27 may be formed at an interval inward from the peripheral edge of the outer surface 9 and may expose the first semiconductor region 6 from the peripheral edge portion of the outer surface 9.

The semiconductor device 1A includes a gate electrode 30 that is arranged on the first main surface 3 (the interlayer insulating film 27). The gate electrode 30 may be referred to as a “gate main surface electrode”. The gate electrode 30 is arranged at an inner portion of the first main surface 3 at an interval from the peripheral edge of the first main surface 3. The gate electrode 30 is arranged on the active surface 8, in this embodiment. Specifically, the gate electrode 30 is arranged on a region adjacent a central portion of the third connecting surface 10C (the third side surface 5C) at the peripheral edge portion of the active surface 8. The gate electrode 30 is formed in a quadrangle shape in plan view, in this embodiment. As a matter of course, the gate electrode 30 may be formed in a polygonal shape other than the quadrangle shape, a circular shape, or an elliptical shape in plan view.

The gate electrode 30 preferably has a planar area of not more than 25% of the first main surface 3. The planar area of the gate electrode 30 may be not more than 10% of the first main surface 3. The gate electrode 30 may have a thickness of not less than 0.5 μm and not more than 15 μm. The gate electrode 30 may include at least one of a Ti film, a TiN film, a W film, an Al film, a Cu film, an Al alloy film, a Cu alloy film and a conductive polysilicon film.

The gate electrode 30 may include at least one of a pure Cu film (Cu film with a purity of not less than 99%), a pure Al film (Al film with a purity of not less than 99%), an AlCu alloy film, an AlSi alloy film and an AlSiCu alloy film. The gate lower conductor layer 31 has a laminated structure that includes the Ti film and the Al alloy film (in this embodiment, AlSiCu alloy film) laminated in that order from the chip 2 side, in this embodiment.

The semiconductor device 1A includes a source electrode 32 that is arranged on the first main surface 3 (the interlayer insulating film 27) at an interval from the gate electrode 30. The source electrode 32 may be referred to as a “source main surface electrode”. The source electrode 32 is arranged at an inner portion of the first main surface 3 at an interval from the peripheral edge of the first main surface 3. The source electrode 32 is arranged on the active surface 8, in this embodiment. The source electrode 32 has a body electrode portion 33 and at least one (in this embodiment, a plurality of) drawer electrode portions 34A, 34B, in this embodiment.

The body electrode portion 33 is arrange at a region on the fourth side surface 5D (the fourth connecting surface 10D) side at an interval from the gate electrode 30 and faces the gate electrode 30 in the first direction X, in plan view. The body electrode portion 33 is formed in a polygonal shape (specifically, quadrangle shape) that has four sides parallel to the first to fourth side surfaces 5A to 5D in plan view, in this embodiment.

The plurality of drawer electrode portions 34A, 34B include a first drawer electrode portion 34A on one side (the first side surface 5A side) and a second drawer electrode portion 34B on the other side (the second side surface 5B side). The first drawer electrode portion 34A is drawn out from the body electrode portion 33 onto a region located on one side (the first side surface 5A side) of the second direction Y with respect to the gate electrode 30, and faces the gate electrode 30 in the second direction Y, in plan view.

The second drawer electrode portion 34B is drawn out from the body electrode portion 33 onto a region located on the other side (the second side surface 5B side) of the second direction Y with respect to the gate electrode 30, and faces the gate electrode 30 in the second direction Y, in plan view. That is, the plurality of drawer electrode portions 34A, 34B sandwich the gate electrode 30 from both sides of the second direction Y, in plan view.

The source electrode 32 (the body electrode portion 33 and the drawer electrode portions 34A, 34B) penetrates the interlayer insulating film 27 and the main surface insulating film 25, and is electrically connected to the plurality of source structures 16, the source region 14 and the plurality of well regions 18. As a matter of course, the source electrode 32 does not may have the drawer electrode portions 34A, 34B and may consist only of the body electrode portion 33.

The source electrode 32 has a planar area exceeding the planar are of the gate electrode 30. The planar area of the source electrode 32 is preferably not less than 50% of the first main surface 3. The planar are of the source electrode 32 is particularly preferably not less than 75% of the first main surface 3. The source electrode 32 may have a thickness of not less than 0.5 μm and not more than 15 μm. The source electrode 32 may include at least one of a Ti film, a TiN film, a W film, an Al film, a Cu film, an Al alloy film, a Cu alloy film and a conductive polysilicon film.

The source electrode 32 may include at least one of a pure Cu film (Cu film with a purity of not less than 99%), a pure Al film (Al film with a purity of not less than 99%), an AlCu alloy film, an AlSi alloy film and an AlSiCu alloy film. The source electrode 32 has a laminated structure that includes the Ti film and the Al alloy film (in this embodiment, AlSiCu alloy film) laminated in that order from the chip 2 side, in this embodiment. The source electrode 32 preferably has the same conductive material as that of the gate electrode 30.

The semiconductor device 1A includes at least one (in this embodiment, a plurality of) gate wirings 36A, 36B that are drawn out from the gate electrode 30 onto the first main surface 3 (the interlayer insulating film 27). The plurality of gate wirings 36A, 36B preferably include the same conductive material as that of the gate electrode 30. The plurality of gate wirings 36A, 36B cover the active surface 8 and do not cover the outer surface 9, in this embodiment. The plurality of gate wirings 36A, 36B are drawn out into a region between the peripheral edge of the active surface 8 and the source electrode 32 and each extends in a band shape along the source electrode 32 in plan view.

Specifically, the plurality of gate wirings 36A, 36B include a first gate wiring 36A and a second gate wiring 36B. The first gate wiring 36A is drawn out from the gate electrode 30 into a region on the first side surface 5A side in plan view. The first gate wiring 36A includes a portion extending as a band shape in the second direction Y along the third side surface 5C and a portion extending as a band shape in the first direction X along the first side surface 5A. The second gate wiring 36B is drawn out from the gate electrode 30 into a region on the second side surface 5B side in plan view. The second gate wiring 36B includes a portion extending as a band shape in the second direction Y along the third side surface 5C and a portion extending as a band shape in the first direction X along the second side surface 5B.

The plurality of gate wirings 36A, 36B intersect (specifically, perpendicularly intersect) both end portions of the plurality of gate structures 15 at the peripheral edge portion of the active surface 8 (the first main surface 3). The plurality of gate wirings 36A, 36B penetrate the interlayer insulating film 27 and are electrically connected to the plurality of gate structures 15. The plurality of gate wirings 36A, 36B may be directly connected to the plurality of gate structures 15, or may be electrically connected to the plurality of gate structures 15 via a conductor film.

The semiconductor device 1A includes a source wiring 37 that is drawn out from the source electrode 32 onto the first main surface 3 (the interlayer insulating film 27). The source wiring 37 preferably includes the same conductive material as that of the source electrode 32. The source wiring 37 is formed in a band shape extending along the peripheral edge of the active surface 8 at a region located on the outer surface 9 side than the plurality of gate wirings 36A, 36B. The source wiring 37 is formed in an annular shape (specifically, a quadrangle annular shape) surrounding the gate electrode 30, the source electrode 32 and the plurality of gate wirings 36A, 36B in plan view, in this embodiment.

The source wiring 37 covers the side wall structure 26 with the interlayer insulating film 27 interposed therebetween and is drawn out from the active surface 8 side to the outer surface 9 side. The source wiring 37 preferably covers a whole region of the side wall structure 26 over an entire circumference. The source wiring 37 penetrates the interlayer insulating film 27 and the main surface insulating film 25 on the outer surface 9 side, and has a portion connected to the outer surface 9 (specifically, the outer contact region 19). The source wiring 37 may penetrate the interlayer insulating film 27 and may be electrically connected to the side wall structure 26.

The semiconductor device 1A includes an upper insulating film 38 that selectively covers the gate electrode 30, the source electrode 32, the plurality of gate wirings 36A, 36B and the source wiring 37. The upper insulating film 38 has a gate opening 39 exposing an inner portion of the gate electrode 30 and covers a peripheral edge portion of the gate electrode 30 over an entire circumference. The gate opening 39 is formed in a quadrangle shape in plan view, in this embodiment.

The upper insulating film 38 has a source opening 40 exposing an inner portion of the source electrode 32 and covers a peripheral edge portion of the source electrode 32 over an entire circumference. The source opening 40 is formed in a polygonal shape along the source electrode 32 in plan view, in this embodiment. The upper insulating film 38 covers whole regions of the plurality of gate wirings 36A, 36B and a whole region of the source wiring 37.

The upper insulating film 38 covers the side wall structure 26 with the interlayer insulating film 27 interposed therebetween, and is drawn out from the active surface 8 side to the outer surface 9 side. The upper insulating film 38 is formed at an interval inward from the peripheral edge of the outer surface 9 (the first to fourth side surfaces 5A to 5D) and covers the outer contact region 19, the outer well region 20 and the plurality of field regions 21. The upper insulating film 38 defines a dicing street 41 with the peripheral edge of the outer surface 9.

The dicing street 41 is formed in a band shape extending along the peripheral edge of the outer surface 9 (the first to fourth side surfaces 5A to 5D) in plan view. The dicing street 41 is formed in an annular shape (specifically, a quadrangle annular shape) surrounding the inner portion of the first main surface 3 (the active surface 8) in plan view, in this embodiment. The dicing street 41 exposes the interlayer insulating film 27, in this embodiment.

As a matter of course, in a case in which the main surface insulating film 25 and the interlayer insulating film 27 expose the outer surface 9, the dicing street 41 may expose the outer surface 9. The dicing street 41 may have a width of not less than 1 μm and not more than 200 μm. The width of the dicing street 41 is a width in a direction orthogonal to an extending direction of the dicing street 41. The width of the dicing street 41 is preferably not less than 5 μm and not more than 50 μm.

The upper insulating film 38 preferably has a thickness exceeding the thickness of the gate electrode 30 and the thickness of the source electrode 32. The thickness of the upper insulating film 38 is preferably less than the thickness of the chip 2. The thickness of the upper insulating film 38 may be not less than 3 μm and not more than 35 μm. The thickness of the upper insulating film 38 is preferably not more than 25 μm.

The upper insulating film 38 has a laminated structure that includes an inorganic insulating film 42 and an organic insulating film 43 laminated in that order form the chip 2 side, in this embodiment. The upper insulating film 38 may include at least one of the inorganic insulating film 42 and the organic insulating film 43, and does not necessarily have to include the inorganic insulating film 42 and the organic insulating film 43 at the same time. The inorganic insulating film 42 selectively covers the gate electrode 30, the source electrode 32, the plurality of gate wirings 36A, 36B and the source wiring 37, and defines a part of the gate opening 39, a part of the source opening 40 and a part of the dicing street 41.

The inorganic insulating film 42 may include at least one of a silicon oxide film, a silicon nitride film and a silicon oxynitride film. The inorganic insulating film 42 preferably includes an insulating material different from that of the interlayer insulating film 27. The inorganic insulating film 42 preferably includes the silicon nitride film. The inorganic insulating film 42 preferably has a thickness less than the thickness of the interlayer insulating film 27. The thickness of the inorganic insulating film 42 may be not less than 0.1 μm and not more than 5 μm.

The organic insulating film 43 selectively covers the inorganic insulating film 42, and defines a part of the gate opening 39, a part of the source opening 40 and a part of the dicing street 41. Specifically, the organic insulating film 43 partially exposes the inorganic insulating film 42 in a wall surface of the gate opening 39. Also, the organic insulating film 43 partially exposes the inorganic insulating film 42 in a wall surface of the source opening 40. Also, the organic insulating film 43 partially exposes the inorganic insulating film 42 in a wall surface of the dicing street 41.

As a matter of course, the organic insulating film 43 may cover the inorganic insulating film 42 such that the inorganic insulating film 42 does not expose from the wall surface of the gate opening 39. The organic insulating film 43 may cover the inorganic insulating film 42 such that the inorganic insulating film 42 does not expose from the wall surface of the source opening 40. The organic insulating film 43 may cover the inorganic insulating film 42 such that the inorganic insulating film 42 does not expose from the wall surface of the dicing street 41. In those cases, the organic insulating film 43 may cover a whole region of the inorganic insulating film 42.

The organic insulating film 43 preferably consists of a resin film other than a thermosetting resin. The organic insulating film 43 may consist of a translucent resin or a transparent resin. The organic insulating film 43 may consist of a negative type photosensitive resin film or a positive type photosensitive resin film. The organic insulating film 43 preferably consists of a polyimide film, a polyamide film or a polybenzoxazole film. The organic insulating film 43 includes the polybenzoxazole film, in this embodiment.

The organic insulating film 43 preferably has a thickness exceeding the thickness of the inorganic insulating film 42. The thickness of the organic insulating film 43 preferably exceeds the thickness of the interlayer insulating film 27. The thickness of the organic insulating film 43 particularly preferably exceeds the thickness of the gate electrode 30 and the thickness of the source electrode 32. The thickness of the organic insulating film 43 may be not less than 3 μm and not more than 30 μm. The thickness of the organic insulating film 43 is preferably not more than 20 μm.

The semiconductor device 1A includes a gate terminal electrode 50 that is arranged on the gate electrode 30. The gate terminal electrode 50 is erected in a columnar shape on a portion of the gate electrode 30 that is exposed from the gate opening 39. The gate terminal electrode 50 has an area less than the area of the gate electrode 30 in plan view and is arranged on the inner portion of the gate electrode 30 at an interval from the peripheral edge of the gate electrode 30.

The gate terminal electrode 50 has a gate terminal surface 51 and a gate terminal side wall 52. The gate terminal surface 51 flatly extends along the first main surface 3. The gate terminal surface 51 may consist of a ground surface with grinding marks. The gate terminal side wall 52 is located on the upper insulating film 38 (specifically, the organic insulating film 43), in this embodiment.

That is, the gate terminal electrode 50 has a portion in contact with the inorganic insulating film 42 and the organic insulating film 43. The gate terminal side wall 52 extends substantially vertically to the normal direction Z. Here, “substantially vertically” includes a mode that extends in the laminate direction while being curved (meandering). The gate terminal side wall 52 includes a portion that faces the gate electrode 30 with the upper insulating film 38 interposed therebetween. The gate terminal side wall 52 preferably consists of a smooth surface without a grinding mark.

The gate terminal electrode 50 has a first protrusion portion 53 that outwardly protrudes at a lower end portion of the gate terminal side wall 52. The first protrusion portion 53 is formed at a region on the upper insulating film 38 (the organic insulating film 43) side than an intermediate portion of the gate terminal side wall 52. The first protrusion portion 53 extends along an outer surface of the upper insulating film 38, and is formed in a tapered shape in which a thickness gradually decreases toward the tip portion from the gate terminal side wall 52 in cross sectional view. The first protrusion portion 53 therefore has a sharp-shaped tip portion with an acute angle. As a matter of course, the gate terminal electrode 50 without the first protrusion portion 53 may be formed.

The gate terminal electrode 50 preferably has a thickness exceeding the thickness of the gate electrode 30. The thickness of the gate terminal electrode 50 is defined by a distance between the gate electrode 30 and the gate terminal surface 51. The thickness of the gate terminal electrode 50 particularly preferably exceeds the thickness of the upper insulating film 38. The thickness of the gate terminal electrode 50 exceeds the thickness of the chip 2, in this embodiment. As a matter of course, the thickness of the gate terminal electrode 50 may be less than the thickness of the chip 2. The thickness of the gate terminal electrode 50 may be not less than 10 μm and not more than 300 μm. The thickness of the gate terminal electrode 50 is preferably not less than 30 μm. The thickness of the gate terminal electrode 50 is particularly preferably not less than 80 μm and not more than 200 μm.

A planar area of the gate terminal electrode 50 is to be adjusted in accordance with the planar area of the first main surface 3. The planar area of the gate terminal electrode 50 is defined by a planar area of the gate terminal surface 51. The planar area of the gate terminal electrode 50 is preferably not more than 25% of the first main surface 3. The planar area of the gate terminal electrode 50 may be not more than 10% of the first main surface 3.

When the first main surface 3 has the planar area of not less than 1 mm square, the planar area of the gate terminal electrode 50 may be not less than 0.4 mm square. The gate terminal electrode 50 may be formed in a polygonal shape (for example, rectangular shape) having a planar area of not less than 0.4 mm×0.7 mm. The gate terminal electrode 50 is formed in a polygonal shape (quadrangle shape with four corners cut out in a rectangular shape) having four sides parallel to the first to fourth side surfaces 5A to 5D in plan view, in this embodiment. As a matter of course, the gate terminal electrode 50 may be formed in a quadrangle shape, a polygonal shape other than the quadrangle shape, a circular shape, or an elliptical shape in plan view.

The gate terminal electrode 50 has a laminated structure that includes a first gate conductor film 55 and a second gate conductor film 56 laminated in that order from the gate electrode 30 side, in this embodiment. The first gate conductor film 55 may include a Ti-based metal film. The first gate conductor film 55 may have a single layered structure consisting of a Ti film or a TiN film. The first gate conductor film 55 may have a laminated structure that includes the Ti film and the TiN film laminated with an arbitrary order.

The first gate conductor film 55 has a thickness less than the thickness of the gate electrode 30. The first gate conductor film 55 covers the gate electrode 30 in a film shape inside the gate opening 39 and is drawn out onto the upper insulating film 38 in a film shape. The first gate conductor film 55 forms a part of the first protrusion portion 53. The first gate conductor film 55 does not necessarily have to be formed and may be omitted.

The second gate conductor film 56 forms a body of the gate terminal electrode 50. The second gate conductor film 56 may include a Cu-based metal film. The Cu-based metal film may be a pure Cu film (Cu film with a purity of not less than 99%) or Cu alloy film. The second gate conductor film 56 includes a pure Cu plating film, in this embodiment. The second gate conductor film 56 preferably has a thickness exceeding the thickness of the gate electrode 30. The thickness of the second gate conductor film 56 particularly preferably exceeds the thickness of the upper insulating film 38. The thickness of the second gate conductor film 56 exceeds the thickness of the chip 2, in this embodiment.

The second gate conductor film 56 covers the gate electrode 30 with the first gate conductor film 55 interposed therebetween inside the gate opening 39, and is drawn out onto the upper insulating film 38 with the first gate conductor film 55 interposed therebetween. The second gate conductor film 56 forms a part of the first protrusion portion 53. That is, the first protrusion portion 53 has a laminated structure that includes the first gate conductor film 55 and the second gate conductor film 56. The second gate conductor film 56 has a thickness exceeding the thickness of the first gate conductor film 55 in the first protrusion portion 53.

The semiconductor device 1A includes a source terminal electrode 60 that is arranged on the source electrode 32. The source terminal electrode 60 is erected in a columnar shape on a portion of the source electrode 32 that is exposed from the source opening 40. The source terminal electrode 60 may have an area less than the area of the source electrode 32 in plan view, and may be arranged on an inner portion of the source electrode 32 at an interval from the peripheral edge of the source electrode 32.

The source terminal electrode 60 is arranged on the body electrode portion 33 of the source electrode 32, and is not arranged on the drawer electrode portions 34A, 34B of the source electrode 32, in this embodiment. A facing area between the gate terminal electrode 50 and the source terminal electrode 60 is thereby reduced. Such a structure is effective in reducing a risk of short-circuit between the gate terminal electrode 50 and the source terminal electrode 60, in a case in which conductive adhesives such as solders and metal pastes are to be adhered to the gate terminal electrode 50 and the source terminal electrode 60. As a matter of course, conductive bonding members such as conductor plates and conducting wires (for example, bonding wires) may be connected to the gate terminal electrode 50 and the source terminal electrode 60. In this case, a risk of short-circuit between the conductive bonding member on the gate terminal electrode 50 side and the conductive bonding member on the source terminal electrode 60 side can be reduced.

The source terminal electrode 60 has a source terminal surface 61 and a source terminal side wall 62. The source terminal surface 61 flatly extends along the first main surface 3. The source terminal surface 61 may consist of a ground surface with grinding marks. The source terminal side wall 62 is located on the upper insulating film 38 (specifically, the organic insulating film 43), in this embodiment.

That is, the source terminal electrode 60 has a portion in contact with the inorganic insulating film 42 and the organic insulating film 43. The source terminal side wall 62 extends substantially vertically to the normal direction Z. Here, “substantially vertically” includes a mode that extends in the laminate direction while being curved (meandering). The source terminal side wall 62 includes a portion that faces the source electrode 32 with the upper insulating film 38 interposed therebetween. The source terminal side wall 62 preferably consists of a smooth surface without a grinding mark.

The source terminal electrode 60 has a second protrusion portion 63 that outwardly protrudes at a lower end portion of the source terminal side wall 62. The second protrusion portion 63 is formed at a region on the upper insulating film 38 (the organic insulating film 43) side than an intermediate portion of the source terminal side wall 62. The second protrusion portion 63 extends along the outer surface of the upper insulating film 38, and is formed in a tapered shape in which a thickness gradually decreases toward the tip portion from the source terminal side wall 62 in cross sectional view. The second protrusion portion 63 therefore has a sharp-shaped tip portion with an acute angle. As a matter of course, the source terminal electrode 60 without the second protrusion portion 63 may be formed.

The source terminal electrode 60 preferably has a thickness exceeding the thickness of the source electrode 32. The thickness of the source terminal electrode 60 is defined by a distance between the source electrode 32 and the source terminal surface 61. The thickness of the source terminal electrode 60 particularly preferably exceeds the thickness of the upper insulating film 38. The thickness of the source terminal electrode 60 exceeds the thickness of the chip 2, in this embodiment.

As a matter of course, the thickness of the source terminal electrode 60 may be less than the thickness of the chip 2. The thickness of the source terminal electrode 60 may be not less than 10 μm and not more than 300 μm. The thickness of the source terminal electrode 60 is preferably not less than 30 μm. The thickness of the source terminal electrode 60 is particularly preferably not less than 80 μm and not more than 200 μm. The thickness of the source terminal electrode 60 is substantially equal to the thickness of the gate terminal electrode 50.

A planar area of the source terminal electrode 60 is to be adjusted in accordance with the planar area of the first main surface 3. The planar area of the source terminal electrode 60 is defined by a planar area of the source terminal surface 61. The planar area of the source terminal electrode 60 preferably exceeds the planar area of the gate terminal electrode 50. The planar area of the source terminal electrode 60 is preferably not less than 50% of the first main surface 3. The planar area of the source terminal electrode 60 is particularly preferably not less than 75% of the first main surface 3.

In a case in which the first main surface 3 has a planar area of not less than 1 mm square, the planar area of the source terminal electrode 60 is preferably not less than 0.8 mm square. In this case, the planar area of each of the source terminal electrode 60 is particularly preferably not less than 1 mm square. The source terminal electrode 60 may be formed in a polygonal shape having a planar area of not less than 1 mm×1.4 mm. The source terminal electrode 60 is formed in a quadrangle shape having four sides parallel to the first to fourth side surfaces 5A to 5D in plan view, in this embodiment. As a matter of course, the source terminal electrode 60 may be formed in a polygonal shape other than the quadrangle shape, a circular shape, or an elliptical shape in plan view.

The source terminal electrode 60 has a laminated structure that includes a first source conductor film 67 and a second source conductor film 68 laminated in that order from the source electrode 32 side, in this embodiment. The first source conductor film 67 may include a Ti-based metal film. The first source conductor film 67 may have a single layered structure consisting of a Ti film or a TiN film. The first source conductor film 67 may have a laminated structure that includes the Ti film and the TiN film with an arbitrary order. The first source conductor film 67 preferably consists of the same conductive material as that of the first gate conductor film 55.

The first source conductor film 67 has a thickness less than the thickness of the source electrode 32. The first source conductor film 67 covers the source electrode 32 in a film shape inside the source opening 40 and is drawn out onto the upper insulating film 38 in a film shape. The first source conductor film 67 forms a part of the second protrusion portion 63. The thickness of the first source conductor film 67 is substantially equal to the thickness of the first gate conductor film 55. The first source conductor film 67 does not necessarily have to be formed and may be omitted.

The second source conductor film 68 forms a body of the source terminal electrode 60. The second source conductor film 68 may include a Cu-based metal film. The Cu-based metal film may be a pure Cu film (Cu film with a purity of not less than 99%) or Cu alloy film. The second source conductor film 68 includes a pure Cu plating film, in this embodiment. The second source conductor film 68 preferably consists of the same conductive material as that of the second gate conductor film 56.

The second source conductor film 68 preferably has a thickness exceeding the thickness of the source electrode 32. The thickness of the second source conductor film 68 particularly preferably exceeds the thickness of the upper insulating film 38. The thickness of the second source conductor film 68 exceeds the thickness of the chip 2, in this embodiment. The thickness of the second source conductor film 68 is substantially equal to the thickness of the second gate conductor film 56.

The second source conductor film 68 covers the source electrode 32 with the first source conductor film 67 interposed therebetween inside the source opening 40, and is drawn out onto the upper insulating film 38 with the first source conductor film 67 interposed therebetween. The second source conductor film 68 forms a part of the second protrusion portion 63. That is, the second protrusion portion 63 has a laminated structure that includes the first source conductor film 67 and the second source conductor film 68. The second source conductor film 68 preferably has a thickness exceeding the thickness of the first source conductor film 67 in the second protrusion portion 63.

The semiconductor device 1A includes a sealing insulator 71 that covers the first main surface 3. The sealing insulator 71 covers a periphery of the gate terminal electrode 50 and a periphery of the source terminal electrode 60 such as to expose a part of the gate terminal electrode 50 and a part of the source terminal electrode 60 on the first main surface 3. Specifically, the sealing insulator 71 covers the active surface 8, the outer surface 9 and the first to fourth connecting surfaces 10A to 10D such as to expose the gate terminal electrode 50 and the source terminal electrode 60.

The sealing insulator 71 exposes the gate terminal surface 51 and the source terminal surface 61 and covers the gate terminal side wall 52 and the source terminal side wall 62. The sealing insulator 71 covers the first protrusion portion 53 of the gate terminal electrode 50 and faces the upper insulating film 38 with the first protrusion portion 53 interposed therebetween, in this embodiment. The sealing insulator 71 suppresses a dropout of the gate terminal electrode 50. Also, the sealing insulator 71 covers the second protrusion portion 63 of the source terminal electrode 60 and faces the upper insulating film 38 with the second protrusion portion 63 interposed therebetween, in this embodiment. The sealing insulator 71 suppresses a dropout of the source terminal electrode 60.

The sealing insulator 71 covers the dicing street 41 at the peripheral edge portion of the outer surface 9. The sealing insulator 71 directly covers the interlayer insulating film 27 at the dicing street 41, in this embodiment. As a matter of course, when the chip 2 (the outer surface 9) or the main surface insulating film 25 is exposed from the dicing street 41, the sealing insulator 71 may directly cover the chip 2 or the main surface insulating film 25 at the dicing street 41.

The sealing insulator 71 has an insulating main surface 72 and an insulating side wall 73. The insulating main surface 72 flatly extends along the first main surface 3. The insulating main surface 72 forms a single flat surface with the gate terminal surface 51 and the source terminal surface 61. The insulating main surface 72 may consist of a ground surface with grinding marks. In this case, the insulating main surface 72 preferably forms a single ground surface with the gate terminal surface 51 and the source terminal surface 61.

The insulating side wall 73 extends toward the chip 2 from a peripheral edge of the insulating main surface 72 and forms a single flat surface with the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the gate electrode 30 and the thickness of the source electrode 32. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm. The thickness of the sealing insulator 71 is substantially equal to the thickness of the gate terminal electrode 50 and the thickness of the source terminal electrode 60.

The sealing insulator 71 includes a matrix resin, a plurality of fillers and a plurality of flexible particles (flexible agent). The sealing insulator 71 is configured such that a mechanical strength is adjusted by the matrix resin, the plurality of fillers and the plurality of flexible particles. The sealing insulator 71 may include at least the matrix resin, and the presence or the absence of the fillers and the flexible particles is optional.

The sealing insulator 71 may include a coloring material such as carbon black that colors the matrix resin. The matrix resin preferably consists of a thermosetting resin. The matrix resin may include at least one of an epoxy resin, a phenol resin and a polyimide resin as an example of the thermosetting resin. The matrix resin includes the epoxy resin, in this embodiment.

The plurality of fillers are added into the matrix resin and are composed of one of or both of spherical objects each consisting of an insulator and indeterminate objects each consisting of an insulator. The indeterminate object has a random shape other than a sphere shape such as a grain shape, a piece shape and a fragment shape. The indeterminate object may have an edge. The plurality of fillers are each composed of the spherical object from a viewpoint of suppressing a damage to be caused by a filler attack, in this embodiment.

The plurality of fillers may include at least one of ceramics, oxides and nitrides. The plurality of fillers each consist of silicon oxide particles (silicon particles), in this embodiment. The plurality of fillers may each have a particle size of not less than 1 nm and not more than 100 μm. The particle sizes of the plurality of fillers are preferably not more than 50 μm.

The sealing insulator 71 preferably include the plurality of fillers differing in the particle sizes. The plurality of fillers may include a plurality of small size fillers, a plurality of medium size fillers and a plurality of large size fillers. The plurality of fillers are preferably added into the matrix resin with a content (density) being in this order of the small size fillers, the medium size fillers and the large size fillers.

The small size fillers may have a thickness less than the thickness of the source electrode 32 (the gate electrode 30). The particle sizes of the small size fillers may be not less than 1 nm and not more than 1 μm. The medium size fillers may have a thickness exceeding the thickness of the source electrode 32 and not more than the thickness of the upper insulating film 38. The particle sizes of the medium size fillers may be not less than 1 μm and not more than 20 μm.

The large size fillers may have a thickness exceeding the thickness of the upper insulating film 38. The plurality of fillers may include at least one large size filler exceeding any one of the thickness of the first semiconductor region 6 (the epitaxial layer), the thickness of the second semiconductor region 7 (the substrate) and the thickness of the chip 2. The particle sizes of the large size fillers may be not less than 20 μm and not more than 100 μm. The particle sizes of the large size fillers are preferably not more than 50 μm.

An average particle size of the plurality of fillers may be not less than 1 μm and not more than 10 μm. The average particle size of the plurality of fillers is preferably not less than 4 μm and not more than 8 μm. As a matter of course, the plurality of fillers does not necessarily have to include all of the small size fillers, the medium size fillers and the large size fillers at the same time, and may be composed of one of or both of the small size fillers and the medium size fillers. For example, in this case, a maximum particle size of the plurality of fillers (the medium size fillers) may be not more than 10 μm.

The sealing insulator 71 may include a plurality of filler fragments each having a broken particle shape in a surface layer portion of the insulating main surface 72 and in a surface layer portion of the insulating side wall 73. The plurality of filler fragments may each be formed by any one of a part of the small size fillers, a part of the medium size fillers and a part of the large size fillers.

The plurality of filler fragments positioned on the insulating main surface 72 side each has a broken portion that is formed along the insulating main surface 72 such as to be oriented to the insulating main surface 72. The plurality of filler fragments positioned on the insulating side wall 73 side each has a broken portion that is formed along the insulating side wall 73 such as to be oriented to the insulating side wall 73. The broken portions of the plurality of filler fragments may be exposed from the insulating main surface 72 and the insulating side wall 73, or may be partially or wholly covered with the matrix resin. The plurality of filler fragments do not affect the structures on the chip 2 side, since the plurality of filler fragments are located in the surface layer portions of the insulating main surface 72 and the insulating side wall 73.

The plurality of flexible particles are added into the matrix resin. The plurality of flexible particles may include at least one of a silicone-based flexible particles, an acrylic-based flexible particles and a butadiene-based flexible particles. The sealing insulator 71 preferably includes the silicone-based flexible particles. The plurality of flexible particles preferably have an average particle size less than the average particle size of the plurality of fillers. The average particle size of the plurality of flexible particles is preferably not less than 1 nm and not more than 1 μm. A maximum particle size of the plurality of flexible particles is preferably not more than 1 μm.

The plurality of flexible particles are added into the matrix resin such that a ratio of a total cross-sectional area with respect to a unit cross-sectional area is to be not less than 0.1% and not more than 10%. In other words, the plurality of flexible particles are added into the matrix resin with a content of a range of not less than 0.1 wt % and not more than 10 wt %. The average particle size and the content of the plurality of flexible particles are to be adjusted in accordance with an elastic modulus to be imparted to the sealing insulator 71 at a time of manufacturing and/or after manufacturing. For example, according to the plurality of flexible particles having the average particle size of a submicron order (=not more than 1 μm), it makes it possible to contribute to a low elastic modulus and a low curing shrinkage of the sealing insulator 71.

The semiconductor device 1A includes a drain electrode 77 (second main surface electrode) that covers the second main surface 4. The drain electrode 77 is electrically connected to the second main surface 4. The drain electrode 77 forms an ohmic contact with the second semiconductor region 7 that is exposed from the second main surface 4. The drain electrode 77 may cover a whole region of the second main surface 4 such as to be continuous with the peripheral edge of the chip 2 (the first to fourth side surfaces 5A to 5D).

The drain electrode 77 may cover the second main surface 4 at an interval from the peripheral edge of the chip 2. The drain electrode 77 is configured such that a drain source voltage of not less than 500 V and not more than 3000 V is to be applied between the source terminal electrode 60 and the drain electrode 77. That is, the chip 2 is formed such that the voltage of not less than 500 V and not more than 3000 V is to be applied between the first main surface 3 and the second main surface 4.

As described above, the semiconductor device 1A includes the chip 2, the gate electrode 30 (the source electrode 32: main surface electrode), the gate terminal electrode 50 (the source terminal electrode 60) and the sealing insulator 71. The chip 2 has the first main surface 3. The gate electrode 30 (the source electrode 32) is arranged on the first main surface 3. The gate terminal electrode 50 (the source terminal electrode 60) is arranged on the gate electrode 30 (the source electrode 32). The sealing insulator 71 covers the periphery of the gate terminal electrode 50 (the source terminal electrode 60) on the first main surface 3 such as to expose the gate terminal electrode 50 (the source terminal electrode 60).

According to this structure, an object to be sealed can be protected from an external force and a humidity (moisture) by the sealing insulator 71. That is, the object to be sealed can be protected from a damage (including peeling) due to the external force and deterioration (including corrosion) due to the humidity. It is therefore possible to suppress shape defects and fluctuations in electrical characteristics. As a result, it is possible to provide the semiconductor device 1A capable of improving reliability.

The semiconductor device 1A preferably includes the upper insulating film 38 that partially covers the gate electrode 30 (the source electrode 32). According to this structure, an object to be covered can be protected from the external force and the humidity with the upper insulating film 38. That is, according to this structure, the object to be sealed can be protected by both of the upper insulating film 38 and the sealing insulator 71.

In such a structure, the sealing insulator 71 preferably has the portion directly covering the upper insulating film 38. The sealing insulator 71 preferably has the portion covering the gate electrode 30 (the source electrode 32) across the upper insulating film 38 interposed therebetween. The gate terminal electrode 50 (the source terminal electrode 60) preferably has the portion that directly covers the upper insulating film 38. The upper insulating film 38 preferably includes any one of or both of the inorganic insulating film 42 and the organic insulating film 43. The organic insulating film 43 preferably consists of the photosensitive resin film.

The upper insulating film 38 is preferably thicker than the gate electrode 30 (the source electrode 32). The upper insulating film 38 is preferably thinner than the chip 2. The sealing insulator 71 is preferably thicker than the gate electrode 30 (the source electrode 32). The sealing insulator 71 is preferably thicker than the upper insulating film 38. The sealing insulator 71 is particularly preferably thicker than the chip 2.

The sealing insulator 71 preferably includes the thermosetting resin (matrix resin). According to this structure, a durability and a waterproofness can be enhanced by the thermosetting resin. The sealing insulator 71 preferably includes the plurality of fillers that are added into the thermosetting resin. According to this structure, a mechanical strength can be adjusted by the plurality of fillers. The sealing insulator 71 preferably includes the flexible particles (flexible agent) that are added into the thermosetting resin. According to this structure, an elastic modulus of the sealing insulator 71 can be adjusted by the flexible particles.

The sealing insulator 71 preferably exposes the gate terminal surface 51 (the source terminal surface 61) of the gate terminal electrode 50 (the source terminal electrode 60) and preferably covers the gate terminal side wall 52 (the source terminal side wall 62). That is, the sealing insulator 71 preferably protects the gate terminal electrode 50 (the source terminal electrode 60) from the gate terminal side wall 52 (the source terminal side wall 62).

In this case, the sealing insulator 71 preferably has the insulating main surface 72 that forms the single flat surface with the gate terminal surface 51 (the source terminal surface 61). The sealing insulator 71 preferably has the insulating side wall 73 that forms the single flat surface with the first to fourth side surfaces 5A to 5D (side surface) of the chip 2. According to this structure, the object to be sealed that is positioned on the first main surface 3 side can be appropriately protected with the sealing insulator 71.

Those above structures are effective when the gate terminal electrode 50 (the source terminal electrode 60) having a relatively large planar area and/or a relatively large thickness is applied to the chip 2 having a relatively large planar area and/or a relatively small thickness. The gate terminal electrode 50 (the source terminal electrode 60) having the relatively large planar area and/or the relatively large thickness is also effective in absorbing a heat generated on the chip 2 side and dissipating the heat to the outside.

For example, the gate terminal electrode 50 (the source terminal electrode 60) is preferably thicker than the gate electrode 30 (the source electrode 32). The gate terminal electrode 50 (the source terminal electrode 60) is preferably thicker than the upper insulating film 38. The gate terminal electrode 50 (the source terminal electrode 60) is particularly preferably thicker than the chip 2. For example, the gate terminal electrode 50 may cover the region of not more than 25% of the first main surface 3 in plan view, and the source terminal electrode 60 may cover the region of not less than 50% of the first main surface 3 in plan view.

For example, the chip 2 may have the first main surface 3 having the area of not less than 1 mm square in plan view. The chip 2 may have the thickness of not more than 100 μm in cross sectional view. The chip 2 preferably has the thickness of not more than 50 μm in cross sectional view. The chip 2 may have the laminated structure that includes the semiconductor substrate and the epitaxial layer. In this case, the epitaxial layer is preferably thicker than the semiconductor substrate.

In those above structures, the chip 2 preferably includes the monocrystal of the wide bandgap semiconductor. The monocrystal of the wide bandgap semiconductor is effective in improving electrical characteristics. Also, according to the monocrystal of the wide bandgap semiconductor, it is possible to achieve a thinning of the chip 2 and an increasing of the planar area of the chip 2 while suppressing a deformation of the chip 2 with a relatively high hardness. The thinning of the chip 2 and the increasing of the planar area of the chip 2 are also effective in improving the electrical characteristics.

The structure having the sealing insulator 71 is also effective in a structure that includes the drain electrode 77 covering the second main surface 4 of the chip 2. The drain electrode 77 forms a potential difference (for example, not less than 500 V and not more than 3000 V) with the source electrode 32 via the chip 2. In particular, in a case in which the chip 2 is relatively thin, a risk of a discharge phenomenon between the peripheral edge of the first main surface 3 and the source electrode 32 increases, since a distance between the source electrode 32 and the drain electrode 77 is shortened. In this point, according to the structure having the sealing insulator 71, an insulation property between the peripheral edge of the first main surface 3 and the source electrode 32 can be improved, and therefore the discharge phenomenon can be suppressed.

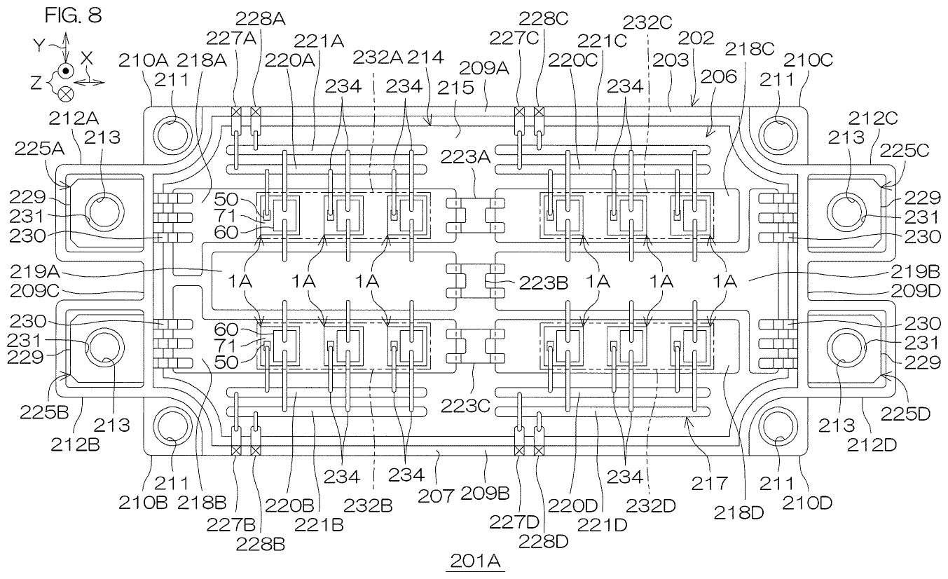

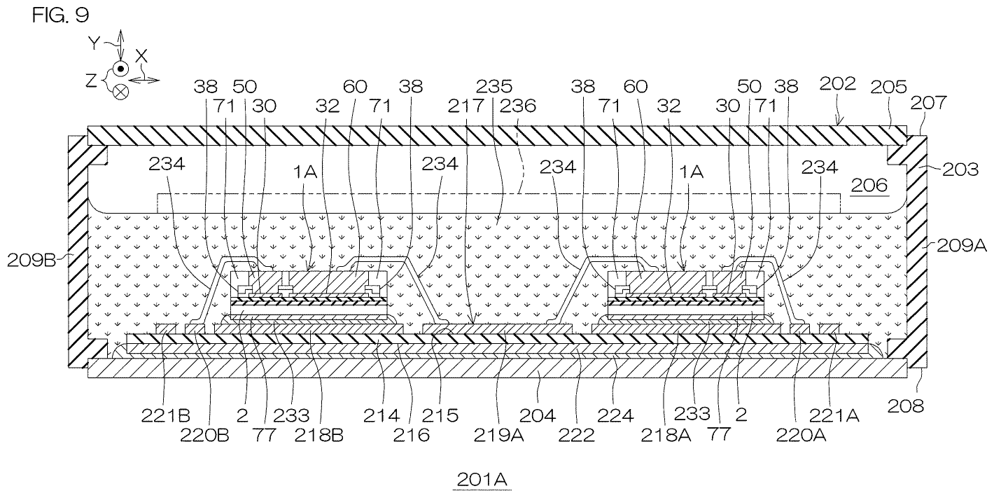

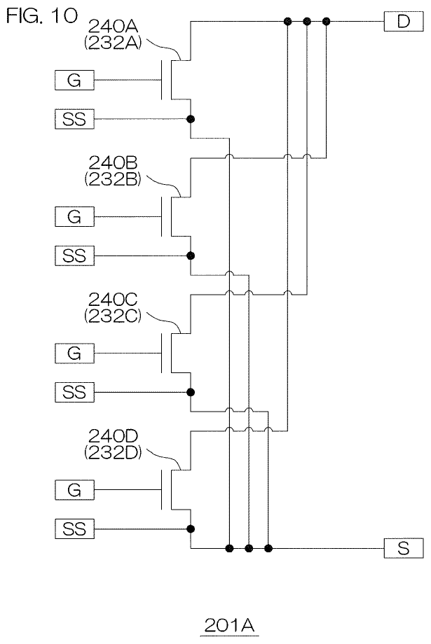

FIG. 8 is a plan view showing a semiconductor module 201A according to a first mode example in which the semiconductor device 1A shown in FIG. 1 is mounted. FIG. 9 is a cross sectional view showing the semiconductor module 201A shown in FIG. 8. FIG. 10 is a circuit diagram showing the semiconductor module 201A shown in FIG. 8. FIG. 9 is a schematic cross sectional view for describing a structure (connection mode) of the semiconductor module 201A, and does not show a cross section of a particular point.

With reference to FIGS. 8 and 9, the semiconductor module 201A includes a housing 202. The housing 202 includes a frame portion 203, a bottom plate 204, and a lid plate 205, and has a housing space 206 defined by these.

The frame portion 203 may be formed of a thermoplastic resin such as Poly Phenylene Sulfide (PPS) resin or Poly Butylene Terephthalate (PBT) resin. The frame portion 203 is formed in a substantially rectangular tubular shape (annular shape) in plan view. Specifically, the frame portion 203 is formed in a substantially rectangular tubular shape (annular shape) having four corners recessed in an arc shape or a rectangular shape toward the housing space 206 in plan view.

The frame portion 203 includes a first end portion 207 on one side (on the upper side of the paper plane of FIG. 9), a second end portion 208 on the other side (on the lower side of the paper plane of FIG. 9), and first to fourth wall portions 209A to 209D. The first to fourth wall portions 209A to 209D form side walls of the housing 202. The first wall portion 209A and the second wall portion 209B extend in the first direction X and oppose in the second direction Y. The first wall portion 209A and the second wall portion 209B form long sides of the housing 202. The third wall portion 209C and the fourth wall portion 209D extend in the second direction Y and oppose in the first direction X. The third wall portion 209C and the fourth wall portion 209D form short sides of the housing 202.

The frame portion 203 has first to fourth flange portions 210A to 210D expanding from the second end portion 208 at four corners toward the opposite side of the housing space 206. The first flange portion 210A is connected to the first wall portion 209A and the third wall portion 209C, the second flange portion 210B is connected to the second wall portion 209B and the third wall portion 209C, the third flange portion 210C is connected to the first wall portion 209A and the fourth wall portion 209D, and the fourth flange portion 210D is connected to the second wall portion 209B and the fourth wall portion 209D. Each of the first to fourth flange portions 210A to 210D has a bolt hole 211.

In this embodiment, the bottom plate 204 is formed by a metal plate as a heat spreader. As a matter of course, the bottom plate 204 may be formed of a thermoplastic resin such as PPS resin or PBT resin. The bottom plate 204 is formed in a substantially rectangular shape in plan view. The bottom plate 204 is attached to the second end portion 208 of the frame portion 203, and defines the housing space 206 together with the frame portion 203. The bottom plate 204 may be attached to the frame portion 203 by an adhesive or may be bolted to a bolt hole formed in an arbitrary point of the frame portion 203.

The lid plate 205 may be formed of a thermoplastic resin such as PPS resin or PBT resin. The lid plate 205 is formed in a substantially rectangular shape in plan view. The lid plate 205 is attached to the first end portion 207 of the frame portion 203 and closes the housing space 206. The lid plate 205 may be attached to the frame portion 203 by an adhesive or may be bolted to a bolt hole formed in an arbitrary point of the frame portion 203.

The semiconductor module 201A includes first to fourth support portions 212A to 212D attached to the frame portion 203. The first to fourth support portions 212A to 212D may be formed of a thermoplastic resin such as PPS resin or PBT resin. In this embodiment, the first to fourth support portions 212A to 212D are formed integrally with the frame portion 203.

The first to second support portions 212A to 212B are attached to the third wall portion 209C of the frame portion 203, and arranged at an interval from each other in the second direction Y. Each of the first to second support portions 212A to 212B protrudes from the third wall portion 209C in a substantially rectangular parallelepiped shape toward the opposite side of the housing 202 in regard to the first direction X.

The third to fourth support portions 212C to 212D are attached to the fourth wall portion 209D of the frame portion 203, and arranged at an interval from each other in the second direction Y. Each of the third to fourth support portions 212C to 212D protrudes from the fourth wall portion 209D in a substantially rectangular parallelepiped shape toward the opposite side of the housing 202 in regard to the first direction X.

Each of the first to fourth support portions 212A to 212D has a substantially quadrangle-shaped recess on an end surface positioned on the first end portion 207 side of the frame portion 203. Each of the first to fourth support portions 212A to 212D has a bolt hole 213. The bolt holes 213 may respectively penetrate the corresponding first to fourth support portions 212A to 212D.

The semiconductor module 201A includes a substrate 214 arranged in the housing space 206. In this embodiment, the substrate 214 is formed in a substantially rectangular shape in plan view, and attached to the bottom plate 204. The substrate 214 may be a wiring substrate such as a Printed Circuit Board (PCB) or a multilayer wiring substrate.

The multilayer wiring substrate may include an insulating laminated structure in which a plurality of insulating layers are laminated, a plurality of wiring layers arranged and multi-layered in the insulating laminated structure, and a plurality of via electrodes that electrically connect the plurality of wiring layers opposing each other in a laminating direction. The substrate 214 includes a first surface 215 on the housing space 206 side, and a second surface 216 on the bottom plate 204 side.

The semiconductor module 201A includes a wiring pattern 217 formed on the first surface 215 of the substrate 214. The wiring pattern 217 is formed by a metal film or a metal plate (metal film in this embodiment). In a case in which the substrate 214 consists of the PCB, the wiring pattern 217 may be an electrode film printed on the first surface 215. In a case in which the substrate 214 consists of the multilayer wiring substrate, the wiring pattern 217 may be the uppermost wiring of the multilayer wiring substrate.

Hereinafter, an example of the wiring pattern 217 shall be described. In this embodiment, the wiring pattern 217 includes first to fourth drain wirings 218A to 218D, first to second source wirings 219A to 219B, first to fourth gate wirings 220A to 220D, and first to fourth sense wirings 221A to 221D.

In this embodiment, the first to fourth drain wirings 218A to 218D are respectively formed at an interval from each other in a band shape extending in the first direction X. The first drain wiring 218A is arranged in the vicinity of a corner portion of the first wall portion 209A and the third wall portion 209C. The second drain wiring 218B is arranged in the vicinity of a corner portion of the second wall portion 209B and the third wall portion 209C. The third drain wiring 218C is arranged in the vicinity of a corner portion of the first wall portion 209A and the fourth wall portion 209D. The fourth drain wiring 218D is arranged in the vicinity of a corner portion of the second wall portion 209B and the fourth wall portion 209D.

In this embodiment, the first to second source wirings 219A to 219B are respectively formed at an interval from each other in a band shape extending in the first direction X. The first source wiring 219A is arranged in a region between the first drain wiring 218A and the second drain wiring 218B. The second source wiring 219B is arranged in a region between the third drain wiring 218C and the fourth drain wiring 218D.

In this embodiment, the first to fourth gate wirings 220A to 220D are respectively formed at an interval from each other in a band shape extending in the first direction X. The first to fourth gate wirings 220A to 220D are thinner than the first to fourth drain wirings 218A to 218D and the first to second source wirings 219A to 219B. The first to fourth gate wirings 220A to 220D are respectively arranged in regions between the first to second wall portions 209A to 209B and the first to fourth drain wirings 218A to 218D.

In this embodiment, the first to fourth sense wirings 221A to 221D are respectively formed at an interval from each other in a band shape extending in the first direction X. The first to fourth sense wirings 221A to 221D are thinner than the first to fourth drain wirings 218A to 218D and the first to second source wirings 219A to 219B. The first to fourth sense wirings 221A to 221D are respectively arranged in regions between the first to second wall portions 209A to 209B and the first to fourth gate wirings 220A to 220D.

The semiconductor module 201A includes a metal layer 222 formed on the second surface 216 of the substrate 214. The metal layer 222 consists of a metal film or a metal plate. In a case in which the substrate 214 consists of the PCB, the metal layer 222 may be a metal film (electrode film) printed on the second surface 216. In a case in which the substrate 214 consists of the multilayer wiring substrate, the metal layer 222 may be the lowermost wiring of the multilayer wiring substrate.

The metal layer 222 preferably covers the second surface 216 over an area exceeding the total area of the wiring pattern 217. The metal layer 222 preferably covers a region of not less than 75% of the second surface 216. The metal layer 222 may cover the substantially whole region of the second surface 216. For example, the metal layer 222 may cover an inner portion of the second surface 216 such as to expose a peripheral edge portion of the second surface 216.

The semiconductor module 201A includes first to third connecting members 223A to 223C that electrically connect the plurality wirings included in the wiring patterns 217. The first to third connecting members 223A to 223C consist of a member different from the wiring pattern 217. In this embodiment, each of the first to third connecting members 223A to 223C is formed by a metal plate formed in an arch shape.

In this embodiment, the first to third connecting members 223A to 223C are formed in an H shape in plan view, however, a planar shape of the first to third connecting members 223A to 223C is arbitrary. The first to third connecting members 223A to 223C may be formed in a polygonal shape such as a quadrangle shape in plan view, for example.

The first connecting member 223A is arranged in a region between the first drain wiring 218A and the third drain wiring 218C which are adjacent to each other in the first direction X, and electrically connects the first drain wiring 218A and the third drain wiring 218C.

The second connecting member 223B is arranged in a region between the second drain wiring 218B and the fourth drain wiring 218D which are adjacent to each other in the first direction X, and electrically connects the second drain wiring 218B and the fourth drain wiring 218D. The third connecting member 223C is arranged in a region between the first source wiring 219A and the second source wiring 219B which are adjacent to each other in the first direction X, and electrically connects the first source wiring 219A and the second source wiring 219B.

The semiconductor module 201A includes an adhesive 224 placed between the substrate 214 and the metal layer 222, the adhesive that connects the substrate 214 and the metal layer 222. In this embodiment, the adhesive 224 consists of a metal adhesive, and thermally and mechanically connects the bottom plate 204 and the metal layer 222.

The adhesive 224 may include a solder or a metal paste. The solder may be a zinc-free solder. The metal paste may include at least one of Au, Ag, and Cu. An Ag paste may consist of an Ag-sintered paste. The AG-sintered paste consists of a paste in which Ag particles of nano-size or micro-size are added to an organic solvent (the same applies hereinafter).

The semiconductor module 201A includes first to fourth terminals 225A to 225D, first to fourth gate terminals 227A to 227D, and first to fourth sense terminals 228A to 228D. In this embodiment, the first to second terminals 225A to 225B are formed as drain terminals, and the third to fourth terminals 225C to 225D are formed as source terminals. The first to fourth terminals 225A to 225D are respectively arranged on the first to fourth support portions 212A to 212D.

Each of the first to fourth terminals 225A to 225D includes a terminal body portion 229 and at least one (in this embodiment, a plurality of) lead portions 230. The terminal body portions 229 are respectively arranged in the recesses of the corresponding first to fourth support portions 212A to 212D. Each of the terminal body portions 229 has a bolt hole 231 whose position is matched with the corresponding bolt hole 213.

The plurality of lead portions 230 penetrate the frame portion 203 (the third wall portion 209C or the fourth wall portion 209D) from the corresponding terminal body portions 229, and are respectively drawn out into the housing space 206. The lead portions 230 of the first to second terminals 225A to 225B are electrically and mechanically connected to the corresponding first to second drain wirings 218A to 218B in the housing space 206. The lead portions 230 of the third to fourth terminals 225C to 225D are electrically and mechanically connected to the second source wiring 219B in the housing space 206.

The first to fourth gate terminals 227A to 227D respectively consist of metal formed in a lead shape (a needle shape or a rod shape). The first to fourth gate terminals 227A to 227D are respectively erected along the frame portion 203 such that at least part of the first to fourth gate terminals 227A to 227D are exposed from the housing space 206. The first to fourth gate terminals 227A to 227D may be arranged along wall surfaces of the frame portion 203 or may be arranged in through holes or recess portions formed in the frame portion 203.

The first to fourth gate terminals 227A to 227D are respectively arranged at positions adjacent the corresponding first to fourth gate wirings 220A to 220D. Each of the first to fourth gate terminals 227A to 227D may have a part extending vertically along the frame portion 203, and a part extending in parallel to the first surface 215 of the substrate 214.

The first to fourth sense terminals 228A to 228D respectively consist of metal formed in a lead shape (a needle shape or a rod shape). The first to fourth sense terminals 228A to 228D are respectively erected along the frame portion 203 such that at least part of the first to fourth sense terminals 228A to 228D are exposed from the housing space 206. The first to fourth sense terminals 228A to 228D may be arranged along the wall surfaces of the frame portion 203 or may be arranged in through holes or recess portions formed in the frame portion 203.

The first to fourth sense terminals 228A to 228D are respectively arranged at positions adjacent the corresponding first to fourth sense wirings 221A to 221D. The first to fourth sense terminals 228A to 228D may be respectively arranged to be next to the corresponding first to fourth gate terminals 227A to 227D.

Each of the first to fourth sense terminals 228A to 228D may have a part extending vertically along the frame portion 203, and a part extending in parallel to the first surface 215 of the substrate 214. The first to fourth sense terminals 228A to 228D are electrically connected to the corresponding first to fourth sense wirings 221A to 221D.

The semiconductor module 201A includes at least one (in this embodiment, the plurality of) semiconductor devices 1A arranged in the housing space 206. In this embodiment, the semiconductor module 201A includes first to fourth groups 232A to 232D each of which includes at least one (in this embodiment, a plurality of) semiconductor devices 1A.

The number of the semiconductor devices 1A included in the first to fourth groups 232A to 232D may be equal or may be different. The semiconductor module 201A does not necessarily have to include all of the first to fourth groups 232A to 232D at the same time as long as an electric circuit to be achieved can be configured, but may include at least one of the first to fourth groups 232A to 232D.

The plurality of semiconductor devices 1A configuring the first group 232A are arranged at an interval from each other on the first drain wiring 218A in a posture that the drain electrodes 77 face the first drain wiring 218A. The plurality of semiconductor devices 1A configuring the second group 232B are arranged at an interval from each other on the second drain wiring 218B in a posture that the drain electrodes 77 face the second drain wiring 218B.

The plurality of semiconductor devices 1A configuring the third group 232C are arranged at an interval from each other on the third drain wiring 218C in a posture that the drain electrodes 77 face the third drain wiring 218C. The plurality of semiconductor devices 1A configuring the fourth group 232D are arranged at an interval from each other on the fourth drain wiring 218D in a posture that the drain electrodes 77 face the fourth drain wiring 218D. In such a way, the drain electrodes 77 of the plurality of semiconductor devices 1A are electrically connected to the first to fourth drain wirings 218A to 218D.

The semiconductor module 201A includes a plurality of conductive adhesives 233 respectively placed between the plurality of semiconductor devices 1A and the first to fourth drain wirings 218A to 218D. The plurality of conductive adhesives 233 mechanically and electrically connect the plurality of semiconductor devices 1A and the first to fourth drain wirings 218A to 218D. The conductive adhesives 233 may include a solder or a metal paste. The solder may be a zinc-free solder. The metal paste may include at least one of Au, Ag, and Cu. An Ag paste may consist of an Ag-sintered paste.

The semiconductor module 201A includes a plurality of conducting wires 234. In this embodiment, the plurality of conducting wires 234 are respectively formed by metal wires (that is, bonding wires). The plurality of conducting wires 234 may include at least one of gold wires, copper wires, and aluminum wires. As a matter of course, the conducting wires 234 may consist of metal plates such as metal clips instead of the metal wires.

The plurality of conducting wires 234 include the plurality of conducting wires 234 that respectively electrically connect the gate terminal electrodes 50 of the plurality of semiconductor devices 1A to the corresponding first to fourth gate wirings 220A to 220D. The plurality of conducting wires 234 include the plurality of conducting wires 234 that respectively electrically connect the source terminal electrodes 60 of the plurality of semiconductor devices 1A to the corresponding first to second source wirings 219A to 219B. The plurality of conducting wires 234 include the plurality of conducting wires 234 that respectively electrically connect the source terminal electrodes 60 of the plurality of semiconductor devices 1A to the corresponding first to fourth sense wirings 221A to 221D.

The plurality of conducting wires 234 include the plurality of conducting wires 234 that respectively electrically connect the first to fourth gate wirings 220A to 220D to the corresponding first to fourth gate terminals 227A to 227D. The plurality of conducting wires 234 include the plurality of conducting wires 234 that respectively electrically connect the first to fourth sense wirings 221A to 221D to the corresponding first to fourth sense terminals 228A to 228D.

The semiconductor module 201A includes an insulating gel-like filling agent 235 that is filled in the housing space 206. The gel-like filling agent 235 protects structures in the housing space 206 from particles, etc. Also, the gel-like filling agent 235 relaxes stress that can be applied to the structures in the housing space 206.

The gel-like filling agent 235 may have a viscosity of not less than 500 mPa·s and not more than 2500 mPa·s (at the time of 23° C.). The viscosity (at the time of 23° C.) of the gel-like filling agent 235 is preferably not less than 700 mPa·s and not more than 1200 mPa·s. The gel-like filling agent 235 may have a specific gravity of not less than 0.8 and not more than 1.3. The specific gravity of the gel-like filling agent 235 is preferably not less than 0.95 and not more than 1.0.

The gel-like filling agent 235 may have a penetration degree of not less than 40 and not more than 90. The penetration degree of the gel-like filling agent 235 is preferably not less than 45 and not more than 70. The penetration degree is a measured value by a ¼ scale cone specified by “JIS K2220”. The gel-like filling agent 235 may have a volume expansion rate of not less than 500 Ppm/K and not more than 2000 Ppm/K. The volume expansion rate of the gel-like filling agent 235 is preferably not less than 1000 Ppm/K and not more than 1500 Ppm/K.

The gel-like filling agent 235 may have a heat transfer rate of not less than 0.01 W/m·K and not more than 0.5 W/m·K. The heat transfer rate of the gel-like filling agent 235 is preferably not less than 0.1 W/m·K and not more than 0.2 W/m·K. The gel-like filling agent 235 may have a volume resistivity of not less than 1×10¹² Ω·m and not more than 1×10¹³ Ω·m. The volume resistivity of the gel-like filling agent 235 is preferably not less than 5×10¹² Ω·m.

The gel-like filling agent 235 may have a dielectric breakdown strength of not less than 10 kV/mm and not more than 100 kV/mm. The dielectric breakdown strength of the gel-like filling agent 235 is preferably not less than 25 kV/mm and not more than 50 kV/mm. The gel-like filling agent 235 may have a sticking force of not less than 1 N and not more than 10 N. The sticking force of the gel-like filling agent 235 is preferably not less than 2 N and not more than 5 N.

The gel-like filling agent 235 may have a surface penetration withstand load of not less than 5 gf and not more than 15 gf. The surface penetration withstand load of the gel-like filling agent 235 is preferably not less than 6 gf and not more than 12 gf. The gel-like filling agent 235 may have an ion residue amount of not more than 5 ppm. The ion residue amount of the gel-like filling agent 235 is preferably not more than 1 ppm. The gel-like filling agent 235 may have a specific inductive capacity of not less than 1 and not more than 10 (at the time of 50 Hz). The specific inductive capacity (at the time of 50 Hz) of the gel-like filling agent 235 is preferably not less than 2 and not more than 7.

In this embodiment, the gel-like filling agent 235 includes a silicone gel and has a moisture retaining property higher than the sealing insulator 71 of the semiconductor device 1A. In this embodiment, the gel-like filling agent 235 is filled up to a height position spaced from the lid plate 205 on the substrate 214 side. As a matter of course, the gel-like filling agent 235 may be filled up to a height position at which the gel-like filling agent 235 contacts the lid plate 205.

Also, a press-down plate 236 for suppressing expansion of the gel-like filling agent 235 (see a two-dot chain line portion of FIG. 9) may be arranged between the gel-like filling agent 235 and the lid plate 205. In this case, the press-down plate 236 may be provided such as to be abutted with the lid plate 205, or may be provided such as not to be abutted with the lid plate 205.

The gel-like filling agent 235 is filled up to a height position at which the plurality of semiconductor devices 1A and the plurality of conducting wires 234 are sealed in the housing space 206, and collectively seals the frame portion 203, the substrate 214, the wiring pattern 217, the first to third connecting members 223A to 223C, part of the first to fourth terminals 225A to 225D (lead portions 230), part of the first to fourth gate terminals 227A to 227D, part of the first to fourth sense wirings 221A to 221D, the plurality of semiconductor devices 1A, the plurality of conductive adhesives 233, and the plurality of conducting wires 234.

In regard to the structure on the semiconductor device 1A side, the gel-like filling agent 235 includes a part that directly covers the first to fourth side surfaces 5A to 5D of the chip 2, and fills the griding marks of the first to fourth side surfaces 5A to 5D. That is, the gel-like filling agent 235 directly covers the first semiconductor region 6 (epitaxial layer) and the second semiconductor region 7 (semiconductor substrate).

In a case in which the first semiconductor region 6 (epitaxial layer) is thicker than the second semiconductor region 7 (semiconductor substrate), a contact area of the gel-like filling agent 235 with respect to the first semiconductor region 6 is larger than a contact area of the gel-like filling agent 235 with respect to the second semiconductor region 7. In a case in which the first semiconductor region 6 (epitaxial layer) is thinner than the second semiconductor region 7 (semiconductor substrate), the contact area of the gel-like filling agent 235 with respect to the first semiconductor region 6 is smaller than the contact area of the gel-like filling agent 235 with respect to the second semiconductor region 7.

The gel-like filling agent 235 includes a part that directly covers a part of the gate terminal electrode 50 exposed from the conducting wire 234, and fills the grinding marks of the gate terminal surface 51. The gel-like filling agent 235 includes a part that directly covers a part of the source terminal electrode 60 exposed from the conducting wire 234, and fills the grinding marks of the source terminal surface 61. The gel-like filling agent 235 includes a part that directly covers the insulating main surface 72 and the insulating side wall 73, and fills the grinding marks of the insulating main surface 72 and the grinding marks of the insulating side wall 73.

The gel-like filling agent 235 does not contact the gate electrode 30, the source electrode 32, the upper insulating film 38, the gate terminal side wall 52 of the gate terminal electrode 50, and the source terminal side wall 62 of the source terminal electrode 60. In regard to the plurality of conducting wires 234, the gel-like filling agent 235 directly covers the whole region of the plurality of conducting wires 234 excluding bonding portions of the plurality of conducting wires 234.

With reference to FIG. 10, the circuit diagram of the semiconductor module 201A is shown by using first to fourth devices 240A to 240D, a drain terminal D, a source terminal S, a plurality of gate terminals G, and a plurality of sense terminals SS. The first to fourth devices 240A to 240D are respectively configured by the first to fourth groups 232A to 232D (the plurality of semiconductor devices 1A).

The drain terminal D is configured by the first to second terminals 225A to 225B, and electrically connected to the drain electrodes 77 of the first to fourth devices 240A to 240D. The source terminal S is configured by the third to fourth terminals 225C to 225D, and electrically connected to the source terminal electrodes 60 of the first to fourth devices 240A to 240D.

The plurality of gate terminals G are respectively configured by the first to fourth gate terminals 227A to 227D, and respectively electrically connected to the gate terminal electrodes 50 of the first to fourth devices 240A to 240D such as to individually transmit gate signals. The plurality of sense terminals SS are respectively configured by the first to fourth sense terminals 228A to 228D, and respectively electrically connected to the source terminal electrodes 60 of the first to fourth devices 240A to 240D such as to individually detect source sense signals.

In this embodiment, the first to fourth devices 240A to 240D (the plurality of semiconductor devices 1A) are controlled in an ON state and an OFF state at the same time. That is, the first to fourth devices 240A to 240D (the plurality of semiconductor devices 1A) configure a single device as a whole. The semiconductor module 201A may be assembled as a device of a power conversion device (power conversion circuit) such as an inverter device (inverter circuit), for example.

The semiconductor module 201A may be assembled into a switching device configuring a high-side arm (upper arm) or a low-side arm (lower arm) of a half-bridge circuit, a full-bridge circuit, a single-phase power conversion circuit, a multi-phase power conversion circuit (three-phase power conversion circuit), etc., for example.

A layout of the wiring pattern 217 is arbitrary, and is not limited to the layout shown in FIG. 8. For example, at least two of the first to fourth drain wirings 218A to 218D may be integrally formed. Also, the first to second source wirings 219A to 219B may be integrally formed. Also, at least two of the first to fourth gate wirings 220A to 220D may be integrally formed. Also, at least two of the first to fourth sense wirings 221A to 221D may be integrally formed.

As a matter of course, the wiring pattern 217 may include five or more drain wirings, three or more source wirings, five or more gate wirings, and five or more sense wirings. Also, the first to third connecting members 223A to 223C are not always required, and may be removed as needed. In addition, the first to fourth gate terminals 227A to 227D may be configured such as to be mechanically and electrically connected to the first to fourth gate wirings 220A to 220D. Also, the first to fourth sense terminals 228A to 228D may be configured such as to be mechanically and electrically connected to the first to fourth sense wirings 221A to 221D.

As described above, the semiconductor module 201A includes the housing 202, the semiconductor device 1A, and the insulating gel-like filling agent 235. The housing 202 has the housing space 206. The semiconductor device 1A includes the chip 2, the gate electrode 30 (the source electrode 32: the main surface electrode), the gate terminal electrode 50 (the source terminal electrode 60), and the sealing insulator 71. The chip 2 has the first main surface 3. The gate electrode 30 (the source electrode 32) is arranged on the first main surface 3.

The gate terminal electrode 50 (the source terminal electrode 60) is arranged on the gate electrode 30 (the source electrode 32). The sealing insulator 71 covers the periphery of the gate terminal electrode 50 (the source terminal electrode 60) on the first main surface 3 such as to expose part of the gate terminal electrode 50 (the source terminal electrode 60). The gel-like filling agent 235 is filled in the housing space 206 such as to contact the sealing insulator 71, and seals the semiconductor device 1A in the housing space 206.

According to this structure, it is possible to provide the semiconductor module 201A provided with the semiconductor device 1A that has high reliability. Also, according to this structure, it is possible to protect the semiconductor device 1A by the gel-like filling agent 235. Also, by the sealing insulator 71, it is possible to protect an object to be sealed of the sealing insulator 71 from stress (including tensile stress and compression stress) of the gel-like filling agent 235 due to a temperature change and humidity of the gel-like filling agent 235.

That is, by the sealing insulator 71, it is possible to protect the object to be sealed from a damage (including peeling) due to the stress of the gel-like filling agent 235 and deterioration (including corrosion) due to the humidity of the gel-like filling agent 235. Thereby, it is possible to suppress shape defects and fluctuations in electrical characteristics. Therefore, it is possible to provide the semiconductor module 201A capable of improving reliability.

The gel-like filling agent 235 is preferably filled up to a height position at which an entirety of the semiconductor device 1A is covered in the housing space 206. In this case, it is possible to properly protect the semiconductor device 1A by the gel-like filling agent 235. The gel-like filling agent 235 preferably includes a silicone gel. The gel-like filling agent 235 preferably contacts the gate terminal electrode 50 (source terminal electrode 60) and the sealing insulator 71, and does not contact the gate electrode 30 (source electrode 32). According to this structure, it is possible to protect the gate electrode 30 (source electrode 32) from the stress and the humidity of the gel-like filling agent 235.

The gate terminal electrode 50 (source terminal electrode 60) is preferably arranged on the gate electrode 30 (source electrode 32) at an interval from the peripheral edge of the gate electrode 30 (source electrode 32). In this case, the sealing insulator 71 preferably covers the peripheral edge portion of the gate electrode 30 (source electrode 32) and the gate terminal electrode 50 (source terminal electrode 60). According to this structure, by the gate terminal electrode 50 (source terminal electrode 60) and the sealing insulator 71, it is possible to protect the gate electrode 30 (source electrode 32) from the stress and the humidity of the gel-like filling agent 235.

The sealing insulator 71 preferably covers the gate terminal side wall 52 (source terminal side wall 62) such as to expose the gate terminal surface 51 (source terminal surface 61). According to this structure, it is possible to suppress the gel-like filling agent 235 from entering a region between the gate terminal side wall 52 (source terminal side wall 62) and the sealing insulator 71. In this case, the gel-like filling agent 235 preferably has a part that directly covers the gate terminal surface 51 (source terminal surface 61). Further, in this case, the gel-like filling agent 235 preferably does not cover the gate terminal side wall 52 (source terminal side wall 62).

The sealing insulator 71 preferably has the insulating main surface 72 that forms a single flat surface with the gate terminal surface 51 (source terminal surface 61). In this case, the gel-like filling agent 235 preferably has the part that directly covers the insulating main surface 72. According to this structure, it is possible to properly suppress the gel-like filling agent 235 from entering the region between the gate terminal side wall 52 (source terminal side wall 62) and the sealing insulator 71.

The gel-like filling agent 235 preferably has the part that directly covers the first to fourth side surfaces 5A to 5D of the chip 2. The gel-like filling agent 235 preferably has a part that directly covers the insulating side wall 73 of the sealing insulator 71. In this case, the sealing insulator 71 preferably has the insulating side wall 73 that forms a single flat surface with the first to fourth side surfaces 5A to 5D of the chip 2. According to this structure, it is possible to suppress the gel-like filling agent 235 from intruding from a region between the first to fourth side surfaces 5A to 5D and the insulating side wall 73.

The semiconductor device 1A preferably includes the upper insulating film 38 that partly covers the gate electrode 30 (source electrode 32). In this case, the sealing insulator 71 preferably covers the upper insulating film 38. According to this structure, by the sealing insulator 71, it is possible to protect the upper insulating film 38 from the stress and the humidity of the gel-like filling agent 235.

In this case, the sealing insulator 71 preferably has a part that covers the gate electrode 30 (source electrode 32) while sandwiching the upper insulating film 38. According to this structure, by the upper insulating film 38 and the sealing insulator 71, it is possible to protect the gate electrode 30 (source electrode 32) from the stress and the humidity of the gel-like filling agent 235.

The gate terminal electrode 50 (source terminal electrode 60) preferably has a part that directly covers the upper insulating film 38. According to this structure, by the gate terminal electrode 50 (source terminal electrode 60), it is possible to protect the upper insulating film 38 from the stress and the humidity of the gel-like filling agent 235. The upper insulating film 38 preferably includes any one of or both of the inorganic insulating film 42 and the organic insulating film 43.

The upper insulating film 38 is preferably thicker than the gate electrode 30 (source electrode 32). The upper insulating film 38 is preferably thinner than the chip 2. The sealing insulator 71 is preferably thicker than the gate electrode 30 (source electrode 32). According to this structure, it is possible to protect the gate electrode 30 (source electrode 32) by the relatively thick sealing insulator 71, and at the same time, to separate the gel-like filling agent 235 from the gate electrode 30 (source electrode 32).

The sealing insulator 71 is preferably thicker than the upper insulating film 38. According to this structure, it is possible to protect the gate electrode 30 (source electrode 32) and the upper insulating film 38 by the relatively thick sealing insulator 71, and at the same time, to separate the gate electrode 30 (source electrode 32) and the upper insulating film 38 from the gel-like filling agent 235. The sealing insulator 71 is particularly preferably thicker than the chip 2. According to this structure, it is possible to protect the object to be sealed by the relatively thick sealing insulator 71, and at the same time, to properly separate the gel-like filling agent 235 from the object to be sealed.

The gate terminal electrode 50 (source terminal electrode 60) is preferably thicker than the gate electrode 30 (source electrode 32). The gate terminal electrode 50 (source terminal electrode 60) is preferably thicker than the upper insulating film 38. The gate terminal electrode 50 (source terminal electrode 60) is particularly preferably thicker than the chip 2.

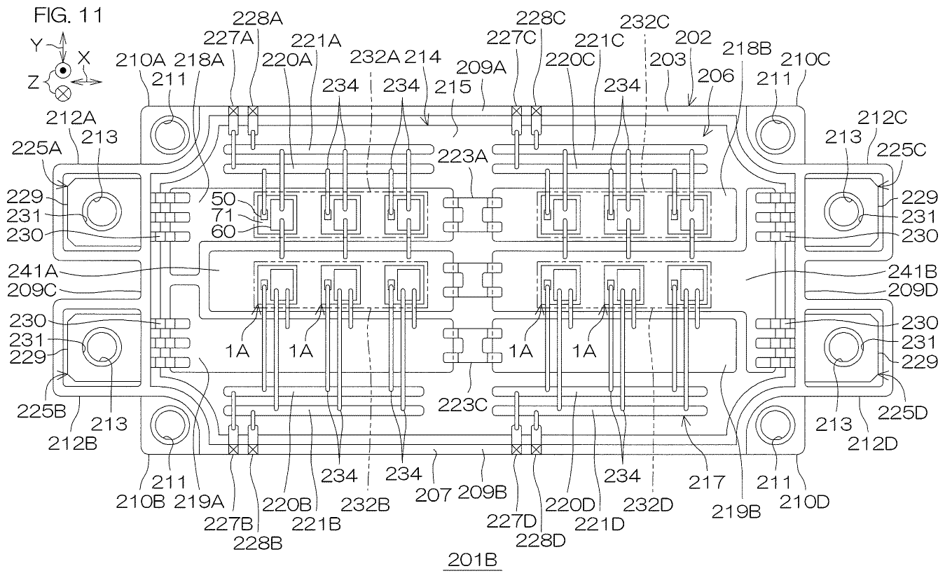

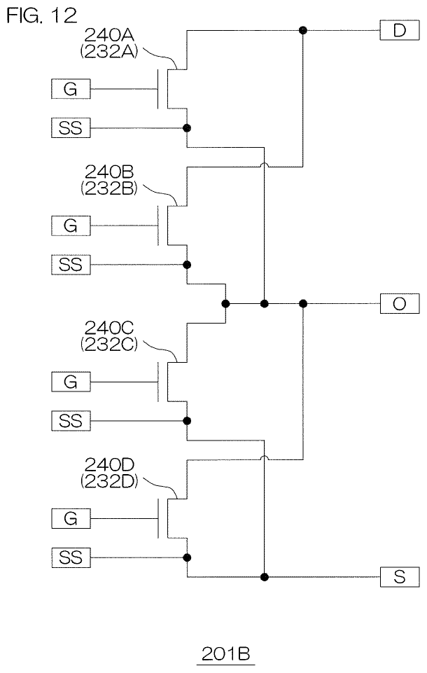

FIG. 11 is a plan view showing a semiconductor module 201B according to a second mode example in which the semiconductor device 1A shown in FIG. 1 is mounted. FIG. 12 is a circuit diagram showing the semiconductor module 201B shown in FIG. 11. The semiconductor module 201B has a mode in which the semiconductor module 201A is deformed, and the same effects as those of the semiconductor module 201A are achieved. Hereinafter, points of the semiconductor module 201B which are different from the semiconductor module 201A shall be described.

With reference to FIG. 11, in this embodiment, the wiring pattern 217 includes first to second drain wirings 218A to 218B, first to second source wirings 219A to 219B, first to second output wirings 241A to 241B, first to fourth gate wirings 220A to 220D, and first to fourth sense wirings 221A to 221D. A layout of the first to fourth gate wirings 220A to 220D and the first to fourth sense wirings 221A to 221D is similar to the case of the semiconductor module 201A.

In this embodiment, the first to second drain wirings 218A to 218B are respectively formed at an interval from each other in a band shape extending in the first direction X. The first drain wiring 218A is arranged in the vicinity of the corner portion of the first wall portion 209A and the third wall portion 209C. The second drain wiring 218B is arranged in the vicinity of the corner portion of the first wall portion 209A and the fourth wall portion 209D.

In this embodiment, the first to second source wirings 219A to 219B are respectively formed at an interval from each other in a band shape extending in the first direction X. The first source wiring 219A is arranged in the vicinity of the corner portion of the second wall portion 209B and the third wall portion 209C. The second drain wiring 218B is arranged in the vicinity of the corner portion of the second wall portion 209B and the fourth wall portion 209D.

In this embodiment, the first to second output wirings 241A to 241B are respectively formed at an interval from each other in a band shape extending in the first direction X. The first output wiring 241A is arranged in a region between the first drain wiring 218A and the first source wiring 219A. The second output wiring 241B is arranged in a region between the second drain wiring 218B and the second source wiring 219B.

In this embodiment, the first connecting member 223A is arranged in the region between the first drain wiring 218A and the second drain wiring 218B, and electrically connects the first drain wiring 218A and the second drain wiring 218B. In this embodiment, the second connecting member 223B is arranged in a region between the first source wiring 219A and the second source wiring 219B, and electrically connects the first source wiring 219A and the second source wiring 219B. The third connecting member 223C is arranged in a region between the first output wiring 241A and the second output wiring 241B, and electrically connects the first output wiring 241A and the second output wiring 241B.

In this embodiment, the first terminal 225A is formed as a drain terminal, and electrically and mechanically connected to the first drain wiring 218A. In this embodiment, the second terminal 225B is formed as a source terminal, and electrically and mechanically connected to the first source wiring 219A. In this embodiment, the third to fourth terminals 225C to 225D are formed as output terminals, and electrically and mechanically connected to the second output wiring 241B.

The semiconductor module 201B includes the first to fourth groups 232A to 232D as with the semiconductor module 201A described above. The first to fourth groups 232A to 232D may include at least one semiconductor device 1A, and the number of the semiconductor device 1A included in the first to fourth groups 232A to 232D is arbitrary. Also, the semiconductor module 201B does not necessarily have to include all of the first to fourth groups 232A to 232D at the same time as long as an electric circuit to be achieved can be configured, but may include at least two of the first to fourth groups 232A to 232D.

The plurality of semiconductor devices 1A configuring the first group 232A are arranged at an interval from each other on the first drain wiring 218A in a posture that the drain electrodes 77 face the first drain wiring 218A. The plurality of semiconductor devices 1A configuring the second group 232B are arranged at an interval from each other on the second drain wiring 218B in a posture that the drain electrodes 77 face the second drain wiring 218B.

The plurality of semiconductor devices 1A configuring the third group 232C are arranged at an interval from each other on the first output wiring 241A in a posture that the drain electrodes 77 face the first output wiring 241A. The plurality of semiconductor devices 1A configuring the fourth group 232D are arranged at an interval from each other on the second output wiring 241B in a posture that the drain electrodes 77 face the second output wiring 241B.

In this embodiment, the plurality of conductive adhesives 233 are respectively placed between the plurality of semiconductor devices 1A and the first to second drain wirings 218A to 218B, and between the plurality of semiconductor devices 1A and the first to second output wirings 241A to 241B.

The plurality of conducting wires 234 include the plurality of conducting wires 234 that respectively connect the gate terminal electrodes 50 of the plurality of semiconductor devices 1A to the corresponding first to fourth gate wirings 220A to 220D. The plurality of conducting wires 234 include the plurality of conducting wires 234 that respectively connect the source terminal electrodes 60 of the plurality of semiconductor devices 1A to the corresponding first to fourth sense wirings 221A to 221D.

The plurality of conducting wires 234 include the plurality of conducting wires 234 that respectively connect the source terminal electrodes 60 of the plurality of semiconductor devices 1A of the first to second groups 232A to 232B to the corresponding first to second output wirings 241A to 241B. The plurality of conducting wires 234 include the plurality of conducting wires 234 that respectively connect the source terminal electrodes 60 of the plurality of semiconductor devices 1A of the third to fourth groups 232C to 232D to the corresponding first to second source wirings 219A to 219B.

With reference to FIG. 12, the circuit diagram of the semiconductor module 201B is shown by using the first to fourth devices 240A to 240D, the drain terminal D, the source terminal S, an output terminal O, the plurality of gate terminals G, and the plurality of sense terminals SS. The first to fourth devices 240A to 240D are respectively configured by the first to fourth groups 232A to 232D (the plurality of semiconductor devices 1A).

The drain terminal is configured by the first terminal 225A, and respectively electrically connected to the drain electrodes 77 of the first to second devices 240A to 240B. The source terminal is configured by the second terminal 225B, and respectively electrically connected to the source terminal electrodes 60 of the third to fourth devices 240C to 240D. The output terminal O is configured by the third to fourth terminals 225C to 225D, and electrically connected to the source terminal electrodes 60 of the first to second devices 240A to 240B and the drain electrodes 77 of the third to fourth devices 240C to 240D.

The plurality of gate terminals G are configured by the first to fourth gate terminals 227A to 227D, and respectively electrically connected to the gate terminal electrodes 50 of the first to fourth devices 240A to 240D such as to individually transmit gate signals. The plurality of sense terminals SS are configured by the first to fourth sense terminals 228A to 228D, and respectively electrically connected to the source terminal electrodes 60 of the first to fourth devices 240A to 240D such as to individually detect source sense signals.

The first to second devices 240A to 240B (the plurality of semiconductor devices 1A) are controlled in an ON state and an OFF state at the same time. That is, the first to second devices 240A to 240B (the plurality of semiconductor devices 1A) configure a single device as a whole. The third to fourth devices 240C to 240D (the plurality of semiconductor devices 1A) are controlled in an ON state and an OFF state at the same time at different timing from the first to second devices 240A to 240B. That is, the third to fourth devices 240C to 240D configure a single device as a whole.

The semiconductor module 201B may be assembled as a switching device of a power conversion device (power conversion circuit) such as an inverter device (inverter circuit), for example. The semiconductor module 201B may be assembled into an arm circuit including a high-side arm (upper arm) and a low-side arm (lower arm) (such as a U-phase arm circuit, a V-phase arm circuit, and a W-phase arm circuit) in a half-bridge circuit, a full-bridge circuit, a single-phase power conversion circuit, a multi-phase power conversion circuit (three-phase power conversion circuit), etc., for example.

Also, a layout of the wiring pattern 217 is arbitrary, and is not limited to the layout shown in FIG. 11. For example, the first to second drain wirings 218A to 218B may be integrally formed. Also, the first to second source wirings 219A to 219B may be integrally formed. Also, the first to second output wirings 241A to 241B may be integrally formed.

Also, at least two of the first to fourth gate wirings 220A to 220D may be integrally formed. Also, at least two of the first to fourth sense wirings 221A to 221D may be integrally formed. As a matter of course, the wiring pattern 217 may include three or more drain wirings, three or more source wirings, three or more output wirings, five or more gate wirings, and five or more sense wirings. Also, the first to third connecting members 223A to 223C are not always required, and may be removed as needed.

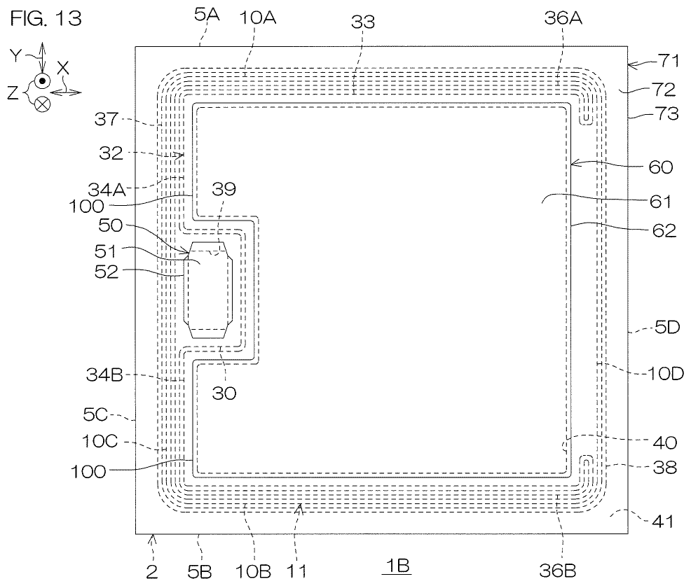

FIG. 13 is a plan view showing a semiconductor device 1B according to a second embodiment. With reference to FIG. 13, the semiconductor device 1B has a modified mode of the semiconductor device 1A. Specifically, the semiconductor device 1B includes the source terminal electrode 60 that has at least one (in this embodiment, a plurality of) drawer terminal portions 100. Specifically, the plurality of drawer terminal portions 100 are each drawn out onto the plurality of drawer electrode portions 34A, 34B of the source electrode 32 such as to oppose the gate terminal electrode 50 in the second direction Y. That is, the plurality of drawer terminal portions 100 sandwich the gate terminal electrode 50 from both sides of the second direction Y in plan view.

As described above, the same effects as those of the semiconductor device 1A are also achieved with the semiconductor device 1B. As a matter of course, the semiconductor module 201A, 201B may include the semiconductor device 1B instead of or in addition to the semiconductor device 1A. With the semiconductor module 201A, 201B including the semiconductor device 1B, the same effects as those described to the semiconductor module 201A, 201B can also be achieved.

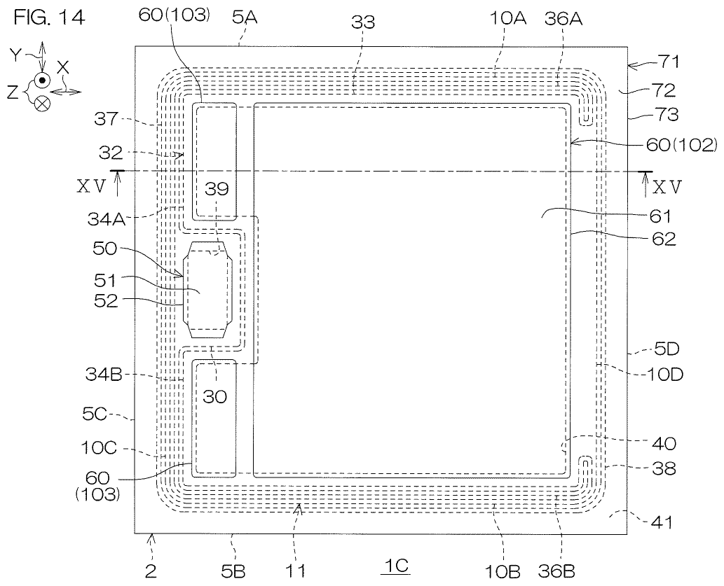

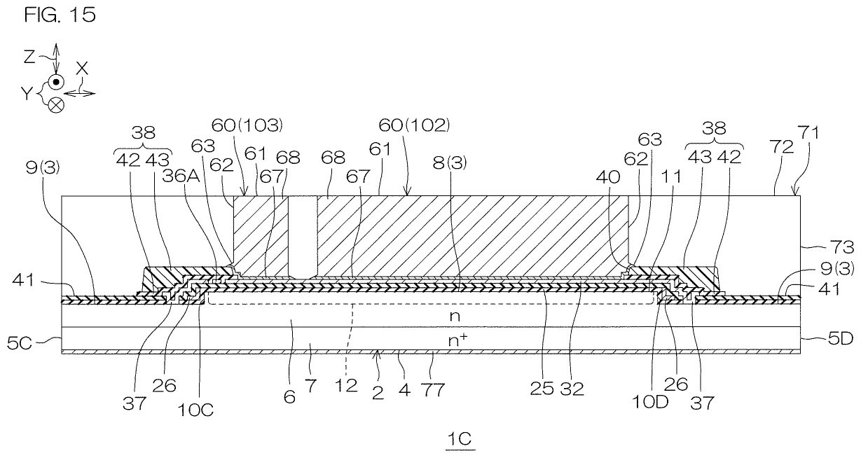

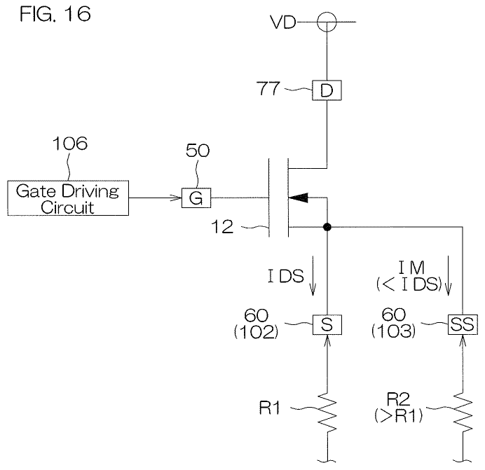

FIG. 14 is a plan view showing a semiconductor device 1C according to a third embodiment. FIG. 15 is a cross sectional view taken along XV-XV line shown in FIG. 14. FIG. 16 is a circuit diagram showing an electrical configuration of the semiconductor device 1C shown in FIG. 14. With reference to FIG. 16 to FIG. 18, the semiconductor device 1C has a modified mode of the semiconductor device 1A.

Specifically, the semiconductor device 1C includes the plurality of source terminal electrodes 60 that are arranged on the source electrode 32 at intervals from each other. The semiconductor device 1C includes at least one (in this embodiment, one) source terminal electrode 60 that is arranged on the body electrode portion 33 of the source electrode 32 and at least one (in this embodiment, a plurality of) source terminal electrodes 60 that are arranged on the plurality of drawer electrode portions 34A, 34B of the source electrode 32, in this embodiment.

The source terminal electrode 60 on the body electrode portion 33 side is formed as a main terminal electrode 102 that conducts a drain source current IDS, in this embodiment. The plurality of source terminal electrodes 60 on the plurality of drawer electrode portions 34A, 34B sides are each formed as a sense terminal electrode 103 that conducts a monitor current IM which monitors the drain source current IDS, in this embodiment. Each of the sense terminal electrodes 103 has an area less than an area of the main terminal electrode 102 in plan view.

One sense terminal electrode 103 is arranged on the first drawer electrode portion 34A and faces the gate terminal electrode 50 in the second direction Y in plan view. The other sense terminal electrode 103 is arranged on the second drawer electrode portion 34B and faces the gate terminal electrode 50 in the second direction Y in plan view. The plurality of sense terminal electrodes 103 therefore sandwich the gate terminal electrode 50 from both sides of the second direction Y in plan view.

With reference to FIG. 16, in the semiconductor device 1C, a gate driving circuit 106 is to be electrically connected to the gate terminal electrode 50, at least one first resistance R1 is to be electrically connected to the main terminal electrode 102, and at least one second resistance R2 is to be electrically connected to the plurality of sense terminal electrodes 103. The first resistance R1 is configured such as to conduct the drain source current IDS that is generated in the semiconductor device 1C. The second resistance R2 is configured such as to conduct the monitor current IM having a value less than that of the drain source current IDS.

The first resistance R1 may be a resistor or a conductive bonding member with a first resistance value. The second resistance R2 may be a resistor or a conductive bonding member with a second resistance value more than the first resistance value. The conductive bonding member may be a conductor plate or the conducting wire 234. That is, at least one conducting wire 234 with the first resistance value may be connected to the main terminal electrode 102.

Also, at least one conducting wire 234 with the second resistance value more than the first resistance value may be connected to at least one of the sense terminal electrodes 103. The second bonding wire may have a line thickness less than a line thickness of the first bonding wire. In this case, a bonding area of the second bonding wire with respect to the sense terminal electrode 103 may be less than a bonding area of the first bonding wire with respect to the main terminal electrode 102.

As described above, the same effects as those of the semiconductor device 1A are also achieved with the semiconductor device 1C. As a matter of course, the semiconductor module 201A, 201B may include the semiconductor device 1C instead of or in addition to the semiconductor device 1A. In this case, the sense terminal electrode 103 in the source terminal electrode 60 may be electrically connected to the corresponding first to fourth sense wirings 221A to 221D via the conducting wire 234. With the semiconductor module 201A, 201B including the semiconductor device 1C, the same effects as those described to the semiconductor module 201A, 201B can also be achieved.

In this embodiment, an example in which the sense terminal electrodes 103 are formed on the drawer electrode portions 34A, 34B, but the arrangement locations of the sense terminal electrodes 103 are arbitrary. Therefore, the sense terminal electrode 103 may be arranged on the body electrode portion 33. In this embodiment, an example in which the sense terminal electrode 103 is applied to the semiconductor device 1A has been shown. As a matter of course, the sense terminal electrode 103 may be applied to the second embodiment.

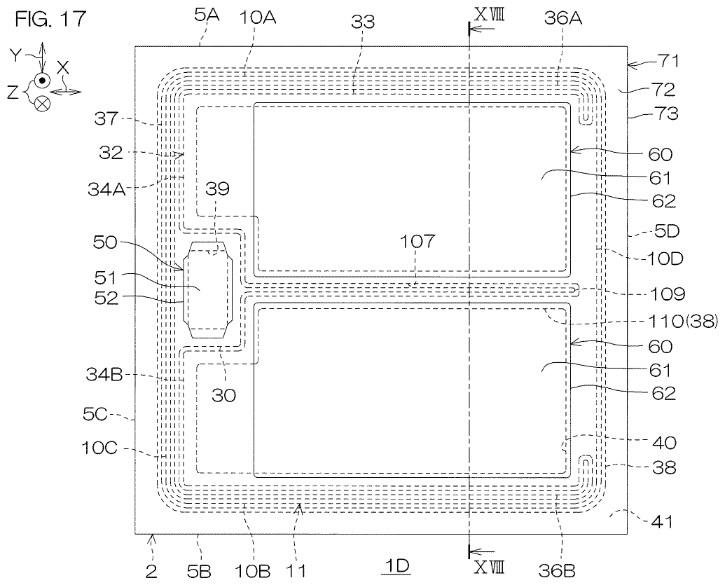

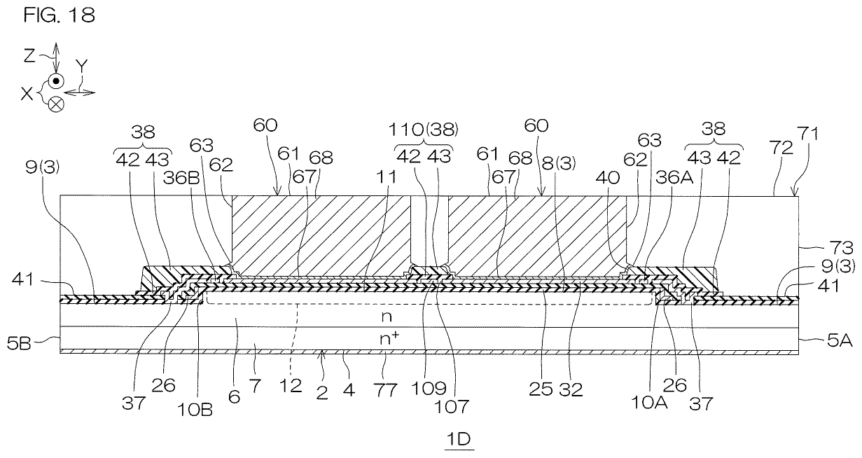

FIG. 17 is a plan view showing a semiconductor device 1D according to a fourth embodiment. FIG. 18 is a cross sectional view taken along XVIII-XVIII line shown in FIG. 17. With reference to FIG. 17 and FIG. 18, the semiconductor device 1D has a modified mode of the semiconductor device 1A. Specifically, the semiconductor device 1D includes a gap portion 107 that formed in the source electrode 32.

The gap portion 107 is formed in the body electrode portion 33 of the source electrode 32. The gap portion 107 penetrates the source electrode 32 to expose a part of the interlayer insulating film 27 in cross sectional view. The gap portion 107 extends in a band shape toward an inner portion of the source electrode 32 from a portion of a wall portion of the source electrode 32 that opposes the gate electrode 30 in the first direction X, in this embodiment.

The gap portion 107 is formed in a band shape extending in the first direction X, in this embodiment. The gap portion 107 crosses a central portion of the source electrode 32 in the first direction X in plan view, in this embodiment. The gap portion 107 has an end portion at a position at an interval inward (to the gate electrode 30 side) from a wall portion of the source electrode 32 on the fourth side surface 5D side in plan view. As a matter of course, the gap portion 107 may divide the source electrode 32 into the second direction Y.

The semiconductor device 1D includes a gate intermediate wiring 109 that is drawn out into the gap portion 107 from the gate electrode 30. The gate intermediate wiring 109 has a laminated structure that includes the first gate conductor film 55 and the second gate conductor film 56 as with the gate electrode 30 (the plurality of gate wiring 36A, 36B). The gate intermediate wiring 109 is formed at an interval from the source electrode 32 and extends in a band shape along the gap portion 107 in plan view.

The gate intermediate wiring 109 penetrates the interlayer insulating film 27 at an inner portion of the active surface 8 (the first main surface 3) and is electrically connected to the plurality of gate structures 15. The gate intermediate wiring 109 may be directly connected to the plurality of gate structures 15, or may be electrically connected to the plurality of gate structures 15 via a conductor film.

The upper insulating film 38 aforementioned includes a gap covering portion 110 that covers the gap portion 107 of the source electrode 32, in this embodiment. The gap covering portion 110 covers a whole region of the gate intermediate wiring 109 inside the gap portion 107. The gap covering portion 110 may be drawn out onto the source electrode 32 from inside the gap portion 107 such as to cover the peripheral edge portion of the source electrode 32.

The semiconductor device 1D includes the plurality of source terminal electrodes 60 that are arranged on the source electrode 32 at an interval from each other, in this embodiment. The plurality of source terminal electrodes 60 are each arranged on the source electrode 32 at an interval from the gap portion 107 and face each other in the second direction Y in plan view. The plurality of source terminal electrodes 60 are arranged such as to expose the gap covering portion 110, in this embodiment.

The plurality of source terminal electrodes 60 are each formed in a quadrangle shape (specifically, rectangular shape extending in the first direction X) in plan view, in this embodiment. The planar shapes of the plurality of source terminal electrodes 60 is arbitrary, and may each be formed in a polygonal shape other than the quadrangle shape, a circular shape, or an elliptical shape in plan view. The plurality of source terminal electrodes 60 may each include the second protrusion portion 63 that is formed on the gap covering portion 110 of the upper insulating film 38.

The sealing insulator 71 aforementioned covers the gap portion 107 at a region between the plurality of source terminal electrodes 60, in this embodiment. The sealing insulator 71 covers the gap covering portion 110 of the upper insulating film 38 at a region between the plurality of source terminal electrodes 60. That is, the sealing insulator 71 covers the gate intermediate wiring 109 with the upper insulating film 38 interposed therebetween.

An example in which the upper insulating film 38 has the gap covering portion 110 has been shown, in this embodiment. However, the presence or the absence of the gap covering portion 110 is arbitrary, and the upper insulating film 38 without the gap covering portion 110 may be formed. In this case, the plurality of source terminal electrodes 60 are formed on the source electrode 32 such as to expose the gate intermediate wiring 109. The sealing insulator 71 directly covers the gate intermediate wiring 109, and electrically isolates the gate intermediate wiring 109 from the source electrode 32. The sealing insulator 71 directly covers a part of the interlayer insulating film 27 that exposes at a region between the source electrode 32 and the gate intermediate wiring 109 inside the gap portion 107.

As described above, the same effects as those of the semiconductor device 1A are also achieved with the semiconductor device 1D. As a matter of course, the semiconductor module 201A, 201B may include the semiconductor device 1D instead of or in addition to the semiconductor device 1A. With the semiconductor module 201A, 201B including the semiconductor device 1D, the same effects as those described to the semiconductor module 201A, 201B can also be achieved.

An example in which the gap portion 107, the gate intermediate wiring 109, the gap covering portion 110, etc., are applied to the semiconductor device 1A has been shown, in this embodiment. As a matter of course, the gap portion 107, the gate intermediate wiring 109, the gap covering portion 110, etc., may be applied to the second and third embodiments.

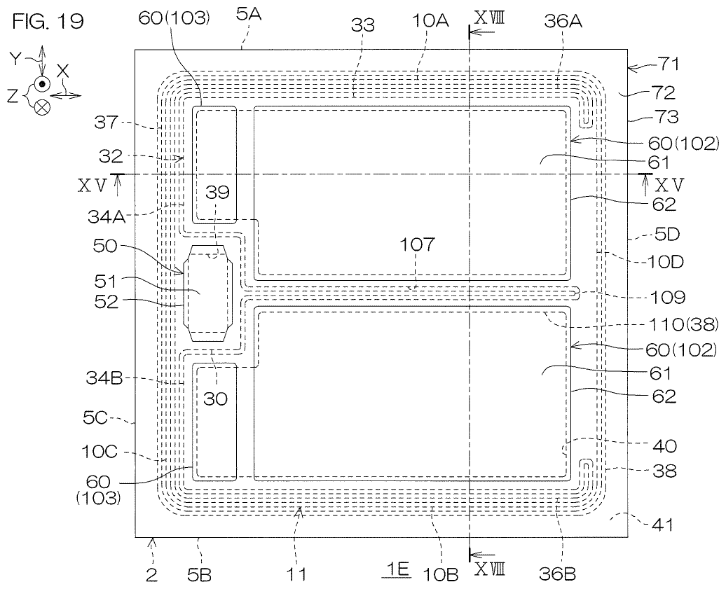

FIG. 19 is a plan view showing a semiconductor device 1E according to a fifth embodiment. With reference to FIG. 19, the semiconductor device 1E has a mode in which the features (structures having the gate intermediate wiring 109) of the semiconductor device 1D according to the fourth embodiment are combined to the features (structures having the sense terminal electrode 103) of the semiconductor device 1C according to the third embodiment. The same effects as those of the semiconductor device 1A are also achieved with the semiconductor device 1E having such a mode.

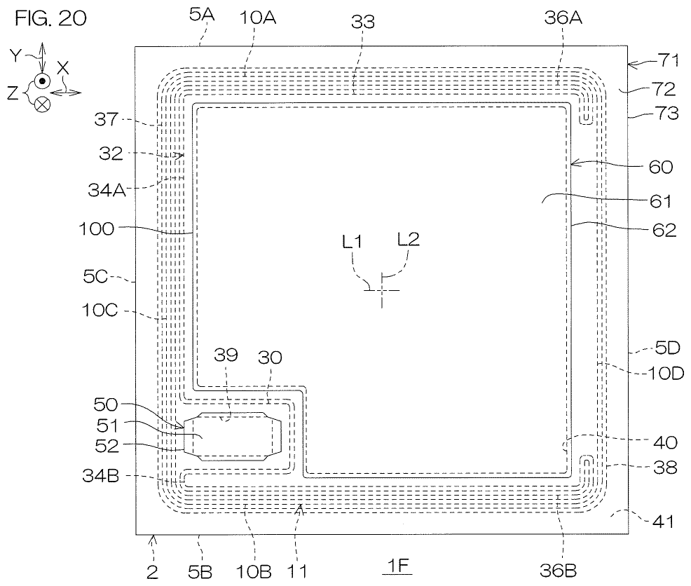

FIG. 20 is a plan view showing a semiconductor device 1F according to an sixth embodiment. With reference to FIG. 20, the semiconductor device 1F has a modified mode of the semiconductor device 1A. Specifically, the semiconductor device 1F has the gate electrode 30 arranged on a region along an arbitrary corner portion of the chip 2.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged at a position offset from both of the first straight line L1 and the second straight line L2. The gate electrode 30 is arranged at a region along a corner portion that connects the second side surface 5B and the third side surface 5C in plan view, in this embodiment.

The plurality of drawer electrode portions 34A, 34B of the source electrode 32 aforementioned sandwich the gate electrode 30 from both sides of the second direction Y in plan view as with the case of the first embodiment. The first drawer electrode portion 34A is drawn out from the body electrode portion 33 with a first planar area. The second drawer electrode portion 34B is drawn out from the body electrode portion 33 with a second planar area less than the first planar area. As a matter of course, the source electrode 32 does not may have the second drawer electrode portion 34B and may only include the body electrode portion 33 and the first drawer electrode portion 34A.

The gate terminal electrode 50 aforementioned is arranged on the gate electrode 30 as with the case of the first embodiment. The gate terminal electrode 50 is arranged at a region along an arbitrary corner portion of the chip 2, in this embodiment. That is, the gate terminal electrode 50 is arranged at a position offset from both of the first straight line L1 and the second straight line L2 in plan view. The gate terminal electrode 50 is arranged at the region along the corner portion that connects the second side surface 5B and the third side surface 5C in plan view, in this embodiment.

The source terminal electrode 60 aforementioned has the drawer terminal portion 100 that is drawn out onto the first drawer electrode portion 34A, in this embodiment. The source terminal electrode 60 does not have the drawer terminal portion 100 that is drawn out onto the second drawer electrode portion 34B, in this embodiment. The drawer terminal portions 100 thereby faces the gate terminal electrode 50 from one side of the second direction Y. The source terminal electrode 60 has portions that face the gate terminal electrode 50 from two directions including the first direction X and the second direction Y by having the drawer terminal portion 100.

As described above, the same effects as those of the semiconductor device 1A are also achieved with the semiconductor device 1F. As a matter of course, the semiconductor module 201A, 201B may include the semiconductor device 1F instead of or in addition to the semiconductor device 1A. With the semiconductor module 201A, 201B including the semiconductor device 1F, the same effects as those described to the semiconductor module 201A, 201B can also be achieved. The structure in which the gate electrode 30 and the gate terminal electrode 50 are arranged on the corner portion of the chip may be applied to the second to fifth embodiment.

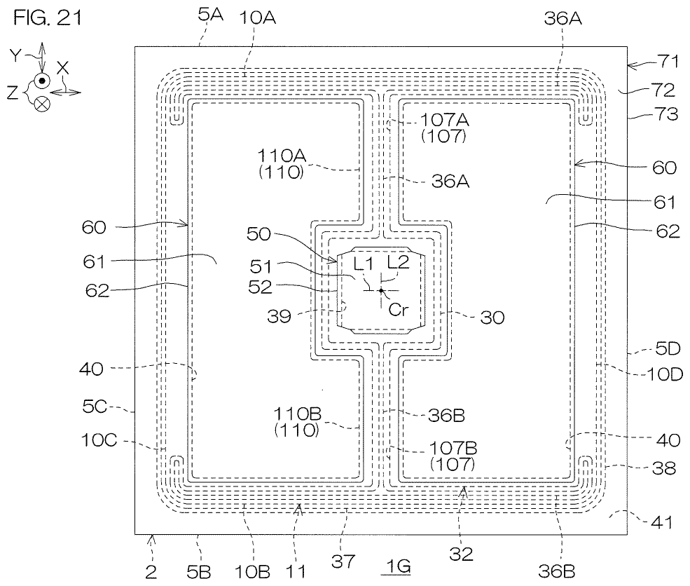

FIG. 21 is a plan view showing a semiconductor device 1G according to a seventh embodiment. With reference to FIG. 21, the semiconductor device 1G has a modified mode of the semiconductor device 1A. Specifically, the semiconductor device 1G has the gate electrode 30 arranged at the central portion of the first main surface 3 (the active surface 8) in plan view.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged such as to overlap an intersecting portion Cr of the first straight line L1 and the second straight line L2. The source electrode 32 aforementioned is formed in an annular shape (specifically, a quadrangle annular shape) surrounding the gate electrode 30 in plan view, in this embodiment.

The semiconductor device 1G includes a plurality of gap portions 107A, 107B that are formed in the source electrode 32. The plurality of gap portions 107A, 107B includes a first gap portions 107A and a second gap portions 107B. The first gap portion 107A crosses a portion of the source electrode 32 that extends in the first direction X in a region on one side (the first side surface 5A side) of the source electrode 32 in the second direction Y. The first gap portion 107A faces the gate electrode 30 in the second direction Y in plan view.

The second gap portion 107B crosses a portion of the source electrode 32 that extends in the first direction X in a region on the other side (the second side surface 5B side) of the source electrode 32 in the second direction Y. The second gap portion 107B faces the gate electrode 30 in the second direction Y in plan view. The second gap portion 107B faces the first gap portion 107A with the gate electrode 30 interposed therebetween in plan view, in this embodiment.

The first gate wiring 36A aforementioned is drawn out into the first gap portion 107A from the gate electrode 30. Specifically, the first gate wiring 36A has a portion extending as a band shape in the second direction Y inside the first gap portion 107A and a portion extending as a band shape in the first direction X along the first side surface 5A (the first connecting surface 10A). The second gate wiring 36B aforementioned is drawn out into the second gap portion 107B from the gate electrode 30. Specifically, the second gate wiring 36B has a portion extending as a band shape in the second direction Y inside the second gap portion 107B and a portion extending as a band shape in the first direction X along the second side surface 5B (the second connecting surface 10B).

The plurality of gate wirings 36A, 36B intersect (specifically, perpendicularly intersect) the both end portions of the plurality of gate structures 15 as with the case of the first embodiment. The plurality of gate wirings 36A, 36B penetrate the interlayer insulating film 27 and are electrically connected to the plurality of gate structures 15. The plurality of gate wirings 36A, 36B may be directly connected the plurality of gate structures 15, or may be electrically connected to the plurality of gate structures 15 via a conductor film.

The source wiring 37 aforementioned is drawn out from a plural portions of the source electrode 32 and surrounds the gate electrode 30, the source electrode 32 and the gate wirings 36A, 36B. As a matter of course, the source wiring 37 may be drawn out from a single portion of the source electrode 32 as with the case of the first embodiment.

The upper insulating film 38 aforementioned includes a plurality of gap covering portions 110A, 110B each cover the plurality of gap portions 107A, 107B, in this embodiment. The plurality of gap covering portions 110A, 110B includes a first gap covering portion 110A and a second gap covering portion 110B. The first gap covering portion 110A covers a whole region of the first gate wiring 36A in the first gap portion 107A. The second gap covering portion 110B covers a whole region of the second gate wiring 36B in the second gap portion 107B. The plurality of gap covering portions 110A, 110B are each drawn out onto the source electrode 32 from inside the plurality of gap portions 107A, 107B such as to cover the peripheral edge portion of the source electrode 32.

The gate terminal electrode 50 aforementioned is arranged on the gate electrode 30 as with the case of the first embodiment. The gate terminal electrode 50 is arranged on the central portion of the first main surface 3 (the active surface 8), in this embodiment. That is, when the first straight line L1 (see two-dot chain line portion) crossing the central portion of the first main surface 3 in the first direction X and the second straight line L2 (see two-dot chain line portion) crossing the central portion of the first main surface 3 in the second direction Y are set, the gate terminal electrode 50 is arranged such as to overlap the intersecting portion Cr of the first straight line L1 and the second straight line L2.

The semiconductor device 1G includes a plurality of source terminal electrodes 60 that are arranged on the source electrode 32, in this embodiment. The plurality of source terminal electrodes 60 are each arranged on the source electrode 32 at intervals from the plurality of gap portions 107A, 107B and face each other in the first direction X in plan view. The plurality of source terminal electrodes 60 are arranged such as to expose the plurality of gap portions 107A, 107B, in this embodiment.

The plurality of source terminal electrodes 60 are each formed in a band shape (specifically, C-letter shape curved along the gate terminal electrode 50) in plan view, in this embodiment. The planar shapes of the plurality of source terminal electrodes 60 are arbitrary, and may each be formed in a quadrangle shape, a polygonal shape other than the quadrangle shape, a circular shape or an elliptical shape. The plurality of source terminal electrodes 60 may each include the second protrusion portion 63 that is arranged on the gap covering portion 110A, 110B of the upper insulating film 38.

The sealing insulator 71 aforementioned covers the plurality of gap portions 107A, 107B at a region between the plurality of source terminal electrodes 60, in this embodiment. The sealing insulator 71 covers the plurality of gap covering portion 110A, 110B at a region between the plurality of source terminal electrodes 60, in this embodiment. That is, the sealing insulator 71 covers the plurality of gate wiring 36A, 36B with the plurality of gap covering portion 110A, 110B interposed therebetween.

An example in which the upper insulating film 38 has the gap covering portion 110A, 110B has been shown, in this embodiment. However, the presence or the absence of the plurality of gap covering portion 110A, 110B is arbitrary and the upper insulating film 38 without the plurality of gap covering portion 110A, 110B may be formed. In this case, the plurality of source terminal electrodes 60 are formed on the source electrode 32 such as to expose the gate wirings 36A, 36B.

The sealing insulator 71 directly covers the gate wirings 36A, 36B and electrically isolates the gate wirings 36A, 36B from the source electrode 32. The sealing insulator 71 directly covers a part of the interlayer insulating film 27 exposed from a region between the source electrode 32 and the gate wirings 36A, 36B inside the plurality of gap portions 107A, 107B.

As described above, the same effects as those of the semiconductor device 1A are also achieved with the semiconductor device 1G. As a matter of course, the semiconductor module 201A, 201B may include the semiconductor device 1G instead of or in addition to the semiconductor device 1A. With the semiconductor module 201A, 201B including the semiconductor device 1G, the same effects as those described to the semiconductor module 201A, 201B can also be achieved. The structure in which the gate electrode 30 and the gate terminal electrode 50 are arranged on the central portion of the chip may be applied to the second to sixth embodiment.

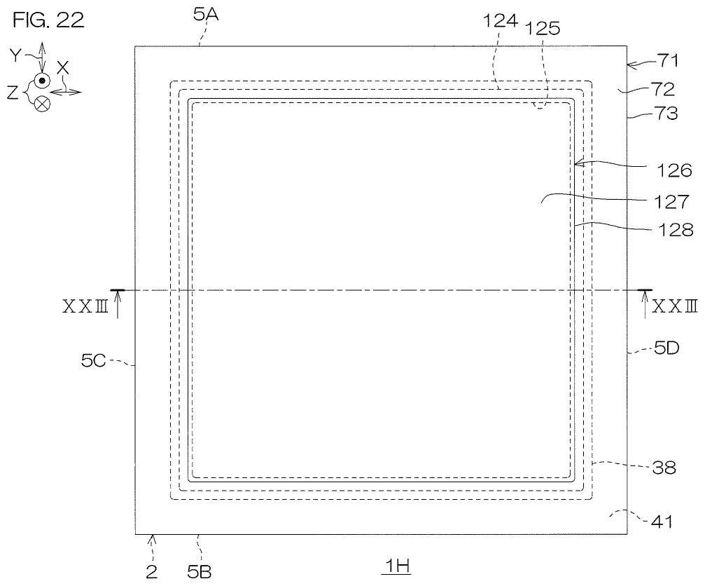

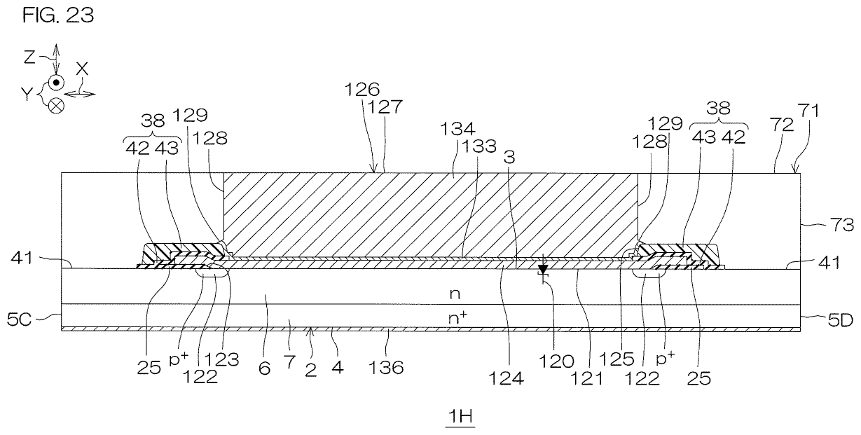

FIG. 22 is a plan view showing a semiconductor device 1H according to a eighth embodiment. FIG. 23 is a cross sectional view taken along XXIII-XXIII line shown in FIG. 22. The semiconductor device 1H includes the chip 2 aforementioned. The chip 2 is free from the mesa portion 11 in this embodiment and has the flat first main surface 3. The semiconductor device 1H has an SBD (Schottky Barrier Diode) structure 120 that is formed in the chip 2 as an example of a diode.

The semiconductor device 1H includes a diode region 121 of the n-type that is formed in an inner portion of the first main surface 3. The diode region 121 is formed by using a part of the first semiconductor region 6, in this embodiment.

The semiconductor device 1H includes a guard region 122 of the p-type that demarcates the diode region 121 from other region at the first main surface 3. The guard region 122 is formed in a surface layer portion of the first semiconductor region 6 at the interval from a peripheral edge of the first main surface 3. The guard region 122 is formed in an annular shape (in this embodiment, a quadrangle annular shape) surrounding the diode region 121 in plan view, in this embodiment. The guard region 122 has an inner end portion on the diode region 121 side and an outer end portion on the peripheral edge side of the first main surface 3.

The semiconductor device 1H includes the main surface insulating film 25 aforementioned that selectively covers the first main surface 3. The main surface insulating film 25 has a diode opening 123 that exposes the diode region 121 and the inner end portion of the guard region 122. The main surface insulating film 25 is formed at an interval inward from the peripheral edge of the first main surface 3 and exposes the first main surface 3 (the first semiconductor region 6) from the peripheral edge portion of the first main surface 3. As a matter of course, the main surface insulating film 25 may cover the peripheral edge portion of the first main surface 3. In this case, the peripheral edge portion of the main surface insulating film 25 may be continuous to the first to fourth side surfaces 5A to 5D.

The semiconductor device 1H includes a first polar electrode 124 (main surface electrode) that is arranged on the first main surface 3. The first polar electrode 124 is an “anode electrode”, in this embodiment. The first polar electrode 124 is arranged at an interval inward from the peripheral edge of the first main surface 3. The first polar electrode 124 is formed in a quadrangle shape along the peripheral edge of the first main surface 3 in plan view, in this embodiment. The first polar electrode 124 enters into the diode opening 123 from on the main surface insulating film 25, and is electrically connected to the first main surface 3 and the inner end portion of guard region 122.

The first polar electrode 124 forms a Schottky junction with the diode region 121 (the first semiconductor region 6). The SBD structure 120 is thereby formed. A planar area of the first polar electrode 124 is preferably not less than 50% of the first main surface 3. The planar area of the first polar electrode 124 is particularly preferably not less than 75% of the first main surface 3. The first polar electrode 124 may have a thickness of not less than 0.5 μm and not more than 15 μm.

The first polar electrode 124 may have a laminated structure that includes a Ti-based metal film and an Al-based metal film. The Ti-based metal film may have a single layered structure consisting of a Ti film or a TiN film. The Ti-based metal film may have a laminated structure that includes the Ti film and the TiN film laminated with an arbitrary order. The Al-based metal film is preferably thicker than the Ti-based metal film. The Al-based metal film may include at least one of a pure Al film (Al film with a purity of not less than 99%), an AlCu alloy film, an AlSi alloy film and an AlSiCu alloy film.

The semiconductor device 1H includes the upper insulating film 38 aforementioned that selectively covers the main surface insulating film 25 and the first polar electrode 124. The upper insulating film 38 has the laminated structure that includes the inorganic insulating film 42 and the organic insulating film 43 laminated in that order from the chip 2 side as with the case of the first embodiment. The upper insulating film 38 has a contact opening 125 exposing an inner portion of the first polar electrode 124 and covers a peripheral edge portion of the first polar electrode 124 over an entire circumference in plan view, in this embodiment. The contact opening 125 is formed in a quadrangle shape in plan view, in this embodiment.

The upper insulating film 38 is formed at an interval inward from the peripheral edge of the first main surface 3 (the first to fourth side surfaces 5A to 5D) and defines the dicing street 41 with the peripheral edge of the first main surface 3. The dicing street 41 is formed in a band shape extending along the peripheral edge of the first main surface 3 in plan view. The dicing street 41 is formed in an annular shape (specifically, a quadrangle annular shape) surrounding the inner portion of the first main surface 3 in plan view, in this embodiment.

The dicing street 41 exposes the first main surface 3 (the first semiconductor region 6), in this embodiment. As a matter of course, in a case in which the main surface insulating film 25 covers the peripheral edge portion of the first main surface 3, the dicing street 41 may expose the main surface insulating film 25. The upper insulating film 38 preferably has a thickness exceeding the thickness of the first polar electrode 124. The thickness of the upper insulating film 38 may be less than the thickness of the chip 2.

The semiconductor device 1H includes a terminal electrode 126 that is arranged on the first polar electrode 124. The terminal electrode 126 is erected in a columnar shape on a portion of the first polar electrode 124 that is exposed from the contact opening 125. The terminal electrode 126 may have an area less than the area of the first polar electrode 124 in plan view, and may be arranged on an inner portion of the first polar electrode 124 at an interval from the peripheral edge of the first polar electrode 124. The terminal electrode 126 is formed in a polygonal shape (in this embodiment, quadrangle shape) having four sides parallel to the first to fourth side surfaces 5A to 5D in plan view, in this embodiment.

The terminal electrode 126 has a terminal surface 127 and a terminal side wall 128. The terminal surface 127 flatly extends along the first main surface. The terminal surface 127 may consist of a ground surface with grinding marks. The terminal side wall 128 is located on the upper insulating film 38 (specifically, the organic insulating film 43), in this embodiment.

That is, the terminal electrode 126 has a portion in contact with the inorganic insulating film 42 and the organic insulating film 43. The terminal side wall 128 extends substantially vertically to the normal direction Z. Here, “substantially vertically” includes a mode that extends in the laminate direction while being curved (meandering). The terminal side wall 128 includes a portion that faces the first polar electrode 124 with the upper insulating film 38 interposed therebetween. The terminal side wall 128 preferably consists of a smooth surface without a grinding mark.

The terminal electrode 126 has a protrusion portion 129 that outwardly protrudes at a lower end portion of the terminal side wall 128. The protrusion portion 129 is formed at a region on the upper insulating film 38 (the organic insulating film 43) side than an intermediate portion of the terminal side wall 128. The protrusion portion 129 extends along the outer surface of the upper insulating film 38, and is formed in a tapered shape in which a thickness gradually decreases toward the tip portion from the terminal side wall 128 in cross sectional view. The protrusion portion 129 therefore has a sharp-shaped tip portion with an acute angle. As a matter of course, the protrusion portion 129 without the protrusion portion 129 may be formed.

The terminal electrode 126 preferably has a thickness exceeding the thickness of the first polar electrode 124. The thickness of the terminal electrode 126 particularly preferably exceeds the thickness of the upper insulating film 38. The thickness of the terminal electrode 126 exceeds the thickness of the chip 2, in this embodiment. As a matter of course, the thickness of the terminal electrode 126 may be less than the thickness of the chip 2.

The thickness of the terminal electrode 126 may be not less than 10 μm and not more than 300 μm. The thickness of the terminal electrode 126 is preferably not less than 30 μm. The thickness of the terminal electrode 126 is particularly preferably not less than 80 μm and not more than 200 μm. The terminal electrode 126 preferably has a planar area of not less than 50% of the first main surface 3. The terminal electrode 126 particularly preferably has a planar area of not less than 75% of the first main surface 3.

The terminal electrode 126 has a laminated structure that includes a first conductor film 133 and a second conductor film 134 laminated in that order from the first polar electrode 124 side, in this embodiment. The first conductor film 133 may include a Ti-based metal film. The first conductor film 133 may have a single layered structure consisting of a Ti film or a TiN film.

The first conductor film 133 may have a laminated structure that includes the Ti film and the TiN film laminated with an arbitrary order. The first conductor film 133 has a thickness less than the thickness of the first polar electrode 124. The first conductor film 133 covers the first polar electrode 124 in a film shape inside the contact opening 125 and is drawn out onto the upper insulating film 38 in a film shape. The first conductor film 133 forms a part of the protrusion portion 129. The first conductor film 133 does not necessarily have to be formed and may be omitted.

The second conductor film 134 forms a body of the terminal electrode 126. The second conductor film 134 may include a Cu-based metal film. The Cu-based metal film may be a pure Cu film (Cu film with a purity of not less than 99%) or Cu alloy film. The second conductor film 134 includes a pure Cu plating film, in this embodiment. The second conductor film 134 preferably has a thickness exceeding the thickness of the first polar electrode 124. The thickness of the second conductor film 134 particularly preferably exceeds the thickness of the upper insulating film 38. The thickness of the second conductor film 134 exceeds the thickness of the chip 2, in this embodiment.

The second conductor film 134 covers the first polar electrode 124 with the first conductor film 133 interposed therebetween inside the contact opening 125, and is drawn out onto the upper insulating film 38 in a film shape with the first conductor film 133 interposed therebetween. The second conductor film 134 forms a part of the protrusion portion 129. That is, the protrusion portion 129 has a laminated structure that includes the first conductor film 133 and the second conductor film 134. The second conductor film 134 has a thickness exceeding a thickness of the first conductor film 133 in the protrusion portion 129.

The semiconductor device 1H includes the sealing insulator 71 aforementioned that covers the first main surface 3. The sealing insulator 71 covers a periphery of the terminal electrode 126 such as to expose a part of the terminal electrode 126 on the first main surface 3, in this embodiment. Specifically, the sealing insulator 71 exposes the terminal surface 127 and covers the terminal side wall 128. The sealing insulator 71 covers the protrusion portion 129 and faces the upper insulating film 38 with the protrusion portion 129 interposed therebetween, in this embodiment. The sealing insulator 71 suppresses a dropout of the terminal electrode 126.

The sealing insulator 71 has a portion that directly covers the upper insulating film 38. The sealing insulator 71 covers the first polar electrode 124 with the upper insulating film 38 interposed therebetween. The sealing insulator 71 covers the dicing street 41 that is demarcated by the upper insulating film 38 at the peripheral edge portion of the first main surface 3. The sealing insulator 71 directly covers the first main surface 3 (the first semiconductor region 6) at the dicing street 41, in this embodiment. As a matter of course, in a case in which the main surface insulating film 25 is exposed from the dicing street 41, the sealing insulator 71 may directly cover the main surface insulating film 25 at the dicing street 41.

The sealing insulator 71 preferably has a thickness exceeding the thickness of the first polar electrode 124. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm.

The sealing insulator 71 has the insulating main surface 72 and the insulating side wall 73. The insulating main surface 72 flatly extends along the first main surface 3. The insulating main surface 72 forms a single flat surface with the terminal surface 127. The insulating main surface 72 may consist of a ground surface with grinding marks. In this case, the insulating main surface 72 preferably forms a single ground surface with the terminal surface 127.

The insulating side wall 73 extends toward the chip 2 from the peripheral edge of the insulating main surface 72 and is continuous to the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The semiconductor device 1H includes a second polar electrode 136 (second main surface electrode) that covers the second main surface 4. The second polar electrode 136 is a “cathode electrode”, in this embodiment. The second polar electrode 136 is electrically connected to the second main surface 4. The second polar electrode 136 forms an ohmic contact with the second semiconductor region 7 exposed from the second main surface 4. The second polar electrode 136 may cover a whole region of the second main surface 4 such as to be continuous with the peripheral edge of the chip 2 (the first to fourth side surfaces 5A to 5D).

The second polar electrode 136 may cover the second main surface 4 at an interval from the peripheral edge of the chip 2. The second polar electrode 136 is configured such that a voltage of not less than 500 V and not more than 3000 V is to be applied between the terminal electrode 126 and second polar electrode 136. That is, the chip 2 is formed such that the voltage of not less than 500 V and not more than 3000 V is to be applied between the first main surface 3 and the second main surface 4.

As described above, the semiconductor device 1H includes the chip 2, the first polar electrode 124 (main surface electrode), the terminal electrode 126 and the sealing insulator 71. The chip 2 has the first main surface 3. The first polar electrode 124 is arranged on the first main surface 3. The second polar electrode 126 is arranged on the first polar electrode 124. The sealing insulator 71 covers the periphery of the terminal electrode 126 on the first main surface 3 such as to expose a part of the terminal electrode 126.

According to this structure, an object to be sealed can be protected from the external force and the humidity by the sealing insulator 71. That is, the object to be sealed can be protected from a damage due to the external force and deterioration due to the humidity. It is therefore possible to suppress shape defects and fluctuations in electrical characteristics. As a result, it is possible to provide the semiconductor device 1H capable of improving reliability.

As described above, the same effects as those of the semiconductor device 1A are also achieved with the semiconductor device 1H. As a matter of course, the semiconductor module 201A, 201B may include the semiconductor device 1H instead of or in addition to the semiconductor device 1A. With the semiconductor module 201A, 201B including the semiconductor device 1H, the same effects as those described to the semiconductor module 201A, 201B can also be achieved.

A mode in which the semiconductor module 201A, 201B includes the semiconductor device 1H instead of the semiconductor device 1A can be obtained by replacing the “drain” with the “cathode” and the “source” with the “anode” in the above description of the semiconductor module 201A, 201B. In this case, the first to second terminals 225A to 225B become cathode terminals and the third to fourth terminals 225C to 225D become anode terminals.

The first to fourth gate terminals 227A to 227D and the first to fourth sense terminals 228A to 228D are not used. The semiconductor device 1H is arranged on the cathode wiring in a posture that the second polar electrode 136 faces the corresponding cathode wiring. The terminal electrode 126 of the semiconductor device 1H is electrically connected to the corresponding anode wiring via the conducting wire 234.

In a case in which the semiconductor module 201A, 201B includes the semiconductor device 1H instead of the semiconductor device 1A, at least one semiconductor device 1H may be connected in parallel to each semiconductor device 1A as a reflux diode. In this case, the semiconductor device 1H is arranged on the first to fourth drain wirings 218A to 218D in a posture that the second polar electrode 136 faces the corresponding first to fourth drain wirings 218A to 218D. The terminal electrode 126 of each semiconductor device 1H is electrically connected to the corresponding first to second source wirings 219A to 219B via the conducting wire 234.

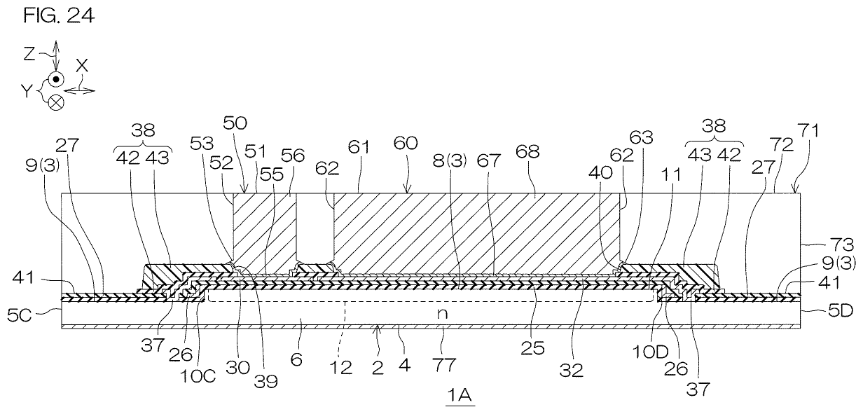

Hereinafter, modified examples to be applied to each embodiment shall be shown. FIG. 24 is a cross sectional view showing a modified example of the chip 2 to be applied to each of the embodiments. In FIG. 24, a mode in which the modified example of the chip 2 is applied to the semiconductor device 1A is shown as an example. However, the modified example of the chip 2 may be applied to any one of the second to eighth embodiments.

With reference to FIG. 24, the semiconductor device 1A does not have the second semiconductor region 7 inside the chip 2 and may only have the first semiconductor region 6 inside the chip 2. In this case, the first semiconductor region 6 is exposed from the first main surface 3, the second main surface 4 and the first to fourth side surfaces 5A to 5D of the chip 2. That is, the chip 2 has a single layered structure that does not have the semiconductor substrate and that consists of the epitaxial layer, in this embodiment.

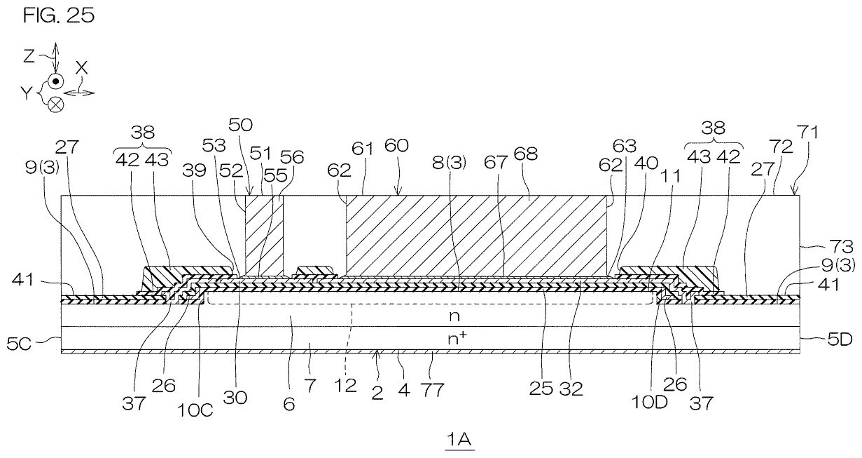

FIG. 25 is a cross sectional view showing a modified example of the sealing insulator 71 to be applied to each of the embodiments. In FIG. 25, a mode in which the modified example of the sealing insulator 71 is applied to the semiconductor device 1A is shown as an example. However, the modified example of the sealing insulator 71 may be applied to any one of the second to tenth embodiments. With reference to FIG. 25, the semiconductor device 1A may include the sealing insulator 71 that covers a whole region of the upper insulating film 38.

In this case, in the first to seventh embodiments, the gate terminal electrode 50 and the source terminal electrode 60 that are not in contact with the upper insulating film 38 are formed. In this case, the sealing insulator 71 may have a portion that directly covers the gate electrode 30 and the source electrode 32. On the other hand, in the eighth embodiment, the terminal electrode 126 that is not in contact with the upper insulating film 38 is formed. In this case, the sealing insulator 71 may have a portion that directly covers the first polar electrode 124.

Each of the above embodiments can be implemented in yet other modes. For example, as long as the structure provides that the gel-like filling agent 235 contacts the sealing insulators 71 of the semiconductor devices 1A to 1H in the housing space 206 of the housing 202, the mode of the semiconductor module 201A, 201B is arbitrary, and not limited to the modes shown in FIGS. 8 to 12. The shape, the layout, the number, etc., of various members configuring the semiconductor module 201A, 201B may be changed as needed.

Also, the semiconductor module 201A, 201B may include at least two of the semiconductor devices 1A to 1H according to the first to eighth embodiments described above at the same time. Also, the characteristics disclosed in the first to eighth embodiments described above can be appropriately combined between those. That is, a mode including at least two characteristics among the characteristics disclosed in the first to eighth embodiments described above at the same time may be adopted.

In each of the above embodiments, the chip 2 having the mesa portion 11 has been shown. However, the chip 2 that does not have the mesa portion 11 and has the first main surface 3 extending in a flat may be adopted. In this case, the side wall structure 26 may be omitted.

In each of the above embodiments, the configurations that has the source wiring 37 have been shown. However, configurations without the source wiring 37 may be adopted. In each of the above embodiments, the gate structure 15 of the trench gate type that controls the channel inside the chip 2 has been shown. However, the gate structure 15 of a planar gate type that controls the channel from on the first main surface 3 may be adopted.

In each of the above embodiments, the configurations in which the MISFET structure 12 and the SBD structure 120 are formed in the different chips 2 have been shown. However, the MISFET structure 12 and the SBD structure 120 may be formed in different regions of the first main surface 3 in the same chip 2. In this case, the SBD structure 120 may be formed as a reflux diode of the MISFET structure 12.

In each of the embodiments, the configuration in which the “first conductive type” is the “n-type” and the “second conductive type” is the “p-type” has been shown. However, in each of the embodiments, a configuration in which the “first conductive type” is the “p-type” and the “second conductive type” is the “n-type” may be adopted. The specific configuration in this case can be obtained by replacing the “n-type” with the “p-type” and at the same time replacing the “p-type” with the “n-type” in the above descriptions and attached drawings.

In each of the embodiments, the second semiconductor region 7 of the “n-type” has been shown. However, the second semiconductor region 7 may be the “p-type”. In this case, an IGBT (Insulated Gate Bipolar Transistor) structure is formed instead of the MISFET structure 12. In this case, in the above descriptions, the “source” of the MISFET structure 12 is replaced with an “emitter” of the IGBT structure, and the “drain” of the MISFET structure 12 is replaced with a “collector” of the IGBT structure. As a matter of course, in a case in which the chip 2 has a single layered structure that consists of the epitaxial layer, the second semiconductor region 7 of the “p-type” may have p-type impurities introduced into a surface layer portion of the second main surface 4 of the chip 2 (the epitaxial layer) by an ion implantation method.

In each of the embodiments, the first direction X and the second direction Y are defined by the extending directions of the first to fourth side surfaces 5A to 5D. However, the first direction X and the second direction Y may be any directions as long as the first direction X and the second direction Y keep a relationship in which the first direction X and the second direction Y intersect (specifically, perpendicularly intersect) each other. For example, the first direction X may be a direction intersecting the first to fourth side surfaces 5A to 5D, and the second direction Y may be a direction intersecting the first to fourth side surfaces 5A to 5D.

Hereinafter, examples of features extracted from the present descriptions and the attached drawings shall be indicated below. Hereinafter, the alphanumeric characters in parentheses represent the corresponding components in the aforementioned embodiments, but are not intended to limit the scope of each clause to the embodiments. The “semiconductor module” in the following clauses may be replaced with a “wide bandgap semiconductor module” or an “SiC semiconductor module” as needed. Also, the “semiconductor device” in the following clauses may be replaced with a “wide bandgap semiconductor device”, an “SiC semiconductor device”, a “semiconductor switching device” or a “semiconductor rectifier device” as needed.

[A1] A semiconductor module (201A, 201B) comprising: a housing (202) that has a housing space (206); a semiconductor device (1A to 1H) that is arranged in the housing space (206), and that has a chip (2) having a main surface (3), a main surface electrode (30, 32, 124) arranged on the main surface (3), a terminal electrode (50, 60, 126) arranged on the main surface electrode (30, 32, 124), and a sealing insulator (71) covering a periphery of the terminal electrode (50, 60, 126) on the main surface (3) such as to expose a part of the terminal electrode (50, 60, 126); and an insulating gel-like filling agent (235) that is filled in the housing space (206) such as to contact the sealing insulator (71), and that seals the semiconductor device (1A to 1H) in the housing space (206).

[A2] The semiconductor module (201A, 201B) according to A1, wherein the gel-like filling agent (235) is filled up to a height position at which an entirety of the semiconductor device (1A to 1H) is covered in the housing space (206).

[A3] The semiconductor module (201A, 201B) according to A1 or A2, wherein the sealing insulator (71) is thicker than the main surface electrode (30, 32, 124).

[A4] The semiconductor module (201A, 201B) according to any one of A1 to A3, wherein the sealing insulator (71) is thicker than the chip (2).

[A5] The semiconductor module (201A, 201B) according to any one of A1 to A4, wherein the sealing insulator (71) includes a thermosetting resin, and the gel-like filling agent (235) includes a silicone gel.

[A6] The semiconductor module (201A, 201B) according to any one of A1 to A5, wherein the gel-like filling agent (235) contacts the terminal electrode (50, 60, 126) and the sealing insulator (71) and does not contact the main surface electrode (30, 32, 124).

[A7] The semiconductor module (201A, 201B) according to any one of A1 to A6, wherein the terminal electrode (50, 60, 126) is arranged on the main surface electrode (30, 32, 124) at an interval from a peripheral edge of the main surface electrode (30, 32, 124), and the sealing insulator (71) covers a peripheral edge portion of the main surface electrode (30, 32, 124) and the terminal electrode (50, 60, 126).

[A8] The semiconductor module (201A, 201B) according to any one of A1 to A7, wherein the terminal electrode (50, 60, 126) has a terminal surface (51, 61, 127) and a terminal side wall (52, 62, 128), the sealing insulator (71) covers the terminal side wall (52, 62, 128) such as to expose the terminal surface (51, 61, 127), and the gel-like filling agent (235) has a part that directly covers the terminal surface (51, 61, 127).

[A9] The semiconductor module (201A, 201B) according to A8, wherein the sealing insulator (71) has an insulating main surface (72) that forms a single flat surface with the terminal surface (51, 61, 127), and the gel-like filling agent (235) has a part that directly covers the insulating main surface (72).

[A10] The semiconductor module (201A, 201B) according to any one of A1 to A9, wherein the chip (2) has a side surface (5A to 5D), and the gel-like filling agent (235) has a part that directly covers the side surface (5A to 5D).

[A11] The semiconductor module (201A, 201B) according to A10, wherein the sealing insulator (71) has an insulating side wall (73) that forms a single flat surface with the side surface (5A to 5D), and the gel-like filling agent (235) has a part that directly covers the insulating side wall (73).

[A12] The semiconductor module (201A, 201B) according to any one of A1 to A11, wherein the semiconductor device (1A to 1H) includes an insulating film (38) that partly covers the main surface electrode (30, 32, 124), and the sealing insulator (71) has a part that covers the insulating film (38).

[A13] The semiconductor module (201A, 201B) according to A12, wherein the gel-like filling agent (235) does not contact the insulating film (38).

[A14] The semiconductor module (201A, 201B) according to A12 or A13, wherein the terminal electrode (50, 60, 126) has a part that directly covers the insulating film (38).

[A15] The semiconductor module (201A, 201B) according to any one of A12 to A14, wherein the insulating film (38) includes any one of or both of an inorganic insulating film (42) and an organic insulating film (43).

[A16] The semiconductor module (201A, 201B) according to any one of A1 to A15, wherein the chip (2) has a laminated structure including a substrate (7) and an epitaxial layer (6), and includes the main surface (3) formed by the epitaxial layer (6).

[A17] The semiconductor module (201A, 201B) according to A16, wherein the epitaxial layer (6) is thicker than the substrate (7).

[A18] The semiconductor module (201A, 201B) according to any one of A1 to A15, wherein the chip (2) has a single layered structure that consists of an epitaxial layer (6).

[A19] The semiconductor module (201A, 201B) according to any one of A1 to A18, wherein the chip (2) includes a monocrystal of a wide bandgap semiconductor.

[A20] The semiconductor module (201A, 201B) according to any one of A1 to A19, further comprising: a wiring (207) arranged in the housing space (206); and a conducting wire (234) connected to the wiring (207) and the semiconductor device (1A to 1H); wherein the gel-like filling agent (235) seals the wiring (207), the semiconductor device (1A to 1H), and the conducting wire (234).

[B1] A semiconductor device (1A to 1H) comprising: a chip (2) having a main surface (3); a main surface electrode (30, 32, 124) arranged on the main surface (3); a terminal electrode (50, 60, 126) arranged on the main surface electrode (30, 32, 124); and a sealing insulator (71) covering a periphery of the terminal electrode (50, 60, 126) on the main surface (3) such as to expose part of the terminal electrode (50, 60, 126).

[B2] The semiconductor device (1A to 1H) according to B1, wherein the sealing insulator (71) is thicker than the main surface electrode (30, 32, 124).

[B3] The semiconductor device (1A to 1H) according to B1 or B2, wherein the sealing insulator (71) is thicker than the chip (2).

[B4] The semiconductor device (1A to 1H) according to any one of B1 to B3, wherein the terminal electrode (50, 60, 126) is thicker than the main surface electrode (30, 32, 124).

[B5] The semiconductor device (1A to 1H) according to any one of B1 to B4, wherein the terminal electrode (50, 60, 126) is thicker than the chip (2).

[B6] The semiconductor device (1A to 1H) according to any one of B1 to B5, wherein the chip (2) has a side surface (5A to 5D), and the sealing insulator (71) has an insulating side wall (73) that forms a single flat surface with the side surface (5A to 5D).

[B7] The semiconductor device (1A to 1H) according to any one of B1 to B6, wherein the side surface (5A to 5D) of the chip (2) consists of a ground surface with grinding marks, and the insulating side wall (73) of the sealing insulator (71) consists of a ground surface with grinding marks.

[B8] The semiconductor device (1A to 1H) according to any one of B1 to B7, wherein the terminal electrode (50, 60, 126) has a terminal surface (51, 61, 127) and a terminal side wall (52, 62, 128), and the sealing insulator (71) exposes the terminal surface (51, 61, 127), and covers the terminal side wall (52, 62, 128).

[B9] The semiconductor device (1A to 1H) according to B8, wherein the sealing insulator (71) has an insulating main surface (72) that forms a single flat surface with the terminal surface (51, 61, 127).

[B10] The semiconductor device (1A to 1H) according to B9, wherein the terminal surface (51, 61, 127) consists of a ground surface with grinding marks, and the insulating main surface (72) consists of a ground surface with grinding marks.

[B11] The semiconductor device (1A to 1H) according to any one of B1 to B10, wherein the sealing insulator (71) includes a thermosetting resin.

[B12] The semiconductor device (1A to 1H) according to B11, wherein the sealing insulator (71) includes fillers added to the thermosetting resin.

[B13] The semiconductor device (1A to 1H) according to B11 or B12, wherein the sealing insulator (71) includes flexible particles added to the thermosetting resin.

[B14] The semiconductor device (1A to 1H) according to any one of B1 to B13, further comprising: an insulating film (38) that partly covers the main surface electrode (30, 32, 124); wherein the sealing insulator (71) has a part that covers the insulating film (38).

[B15] The semiconductor device (1A to 1H) according to B14, wherein the sealing insulator (71) has a part that faces the gate electrode (30, 32, 124) across the insulating film (38).

[B16] The semiconductor device (1A to 1H) according to B14 or B15, wherein the main surface electrode (30, 32, 124) has a part that directly covers the insulating film (38).

[B17] The semiconductor device (1A to 1H) according to any one of B14 to B16, wherein the insulating film (38) includes at least one of an inorganic film (42) and an organic film (43).

[B18] The semiconductor device (1A to 1H) according to any one of B1 to B17, wherein the chip (2) has a laminated structure that includes a substrate (7) and an epitaxial layer (6).

[B19] The semiconductor device (1A to 1H) according to B14, wherein the substrate (7) is thinner than the epitaxial layer (6).

[B20] The semiconductor device (1A to 1H) according to any one of B1 to B17, wherein the chip (2) has a single layered structure that consists of an epitaxial layer (6).

[B21] The semiconductor device (1A to 1H) according to any one of B1 to B20, wherein the chip (2) includes a monocrystal of a wide bandgap semiconductor.

[B22] The semiconductor device (1A to 1H) according to any one of B1 to B21, wherein the chip (2) includes an SiC monocrystal.

[B23] A semiconductor module (201A, 201B) comprising: a housing (202) that has a housing space (206); and the semiconductor device (1A to 1H) according to any one of B1 to B22 that is arranged in the housing space (206).

[B24] The semiconductor module (201A, 201B) according to B23, further comprising: a gel-like filling agent (235) that seals the semiconductor device (1A to 1H) in the housing space (206).

Although the embodiments are described above in detail, these are only specific examples used for clarifying technical contents, and the scope of the present invention should not be interpreted while being limited to these specific examples but only limited by the attached claims.

What is claimed is:

1. A semiconductor module comprising:
a housing that has a housing space;
a semiconductor device that is arranged in the housing space, and that has a chip having a main surface, a main surface electrode arranged on the main surface, a terminal electrode arranged on the main surface electrode, and a sealing insulator covering a periphery of the terminal electrode on the main surface such as to expose a part of the terminal electrode; and
an insulating gel-like filling agent that is filled in the housing space such as to contact the sealing insulator, and that seals the semiconductor device in the housing space.

2. The semiconductor module according to claim 1,
wherein the gel-like filling agent is filled up to a height position at which an entirety of the semiconductor device is covered in the housing space.

3. The semiconductor module according to claim 1,
wherein the sealing insulator is thicker than the main surface electrode.

4. The semiconductor module according to claim 1,
wherein the sealing insulator is thicker than the chip.

5. The semiconductor module according to claim 1,
wherein the sealing insulator includes a thermosetting resin, and
the gel-like filling agent includes a silicone gel.

6. The semiconductor module according to claim 1,
wherein the gel-like filling agent contacts the terminal electrode and the sealing insulator and does not contact the main surface electrode.

7. The semiconductor module according to claim 1,
wherein the terminal electrode is arranged on the main surface electrode at an interval from a peripheral edge of the main surface electrode, and
the sealing insulator covers a peripheral edge portion of the main surface electrode and the terminal electrode.

8. The semiconductor module according to claim 1,
wherein the terminal electrode has a terminal surface and a terminal side wall,
the sealing insulator covers the terminal side wall such as to expose the terminal surface, and
the gel-like filling agent has a part that directly covers the terminal surface.

9. The semiconductor module according to claim 8,
wherein the sealing insulator has an insulating main surface that forms a single flat surface with the terminal surface, and
the gel-like filling agent has a part that directly covers the insulating main surface.

10. The semiconductor module according to claim 1,
wherein the chip has a side surface, and
the gel-like filling agent has a part that directly covers the side surface.

11. The semiconductor module according to claim 10,
wherein the sealing insulator has an insulating side wall that forms a single flat surface with the side surface, and
the gel-like filling agent has a part that directly covers the insulating side wall.

12. The semiconductor module according to claim 1,
wherein the semiconductor device includes an insulating film that partly covers the main surface electrode, and
the sealing insulator has a part that covers the insulating film.

13. The semiconductor module according to claim 12,
wherein the gel-like filling agent does not contact the insulating film.

14. The semiconductor module according to claim 12,
wherein the terminal electrode has a part that directly covers the insulating film.

15. The semiconductor module according to claim 12,
wherein the insulating film includes any one of or both of an inorganic insulating film and an organic insulating film.

16. The semiconductor module according to claim 1,
wherein the chip has a laminated structure including a substrate and an epitaxial layer, and includes the main surface formed by the epitaxial layer.

17. The semiconductor module according to claim 16,
wherein the epitaxial layer is thicker than the substrate.

18. The semiconductor module according to claim 1,
wherein the chip has a single layered structure that consists of an epitaxial layer.

19. The semiconductor module according to claim 1,
wherein the chip includes a monocrystal of a wide bandgap semiconductor.

20. The semiconductor module according to claim 1, further comprising:
a wiring arranged in the housing space; and
a conducting wire connected to the wiring and the semiconductor device;
wherein the gel-like filling agent seals the wiring, the semiconductor device, and the conducting wire.
